(19) United States
(12) Patent Application Publication
(10) Pub. No.: US 2005/0073039 A1
(43) Pub. Date: Apr. 7, 2005

(54) Semiconductor device and method of fabricating the same

(75) Inventors: Yasumasa Kasuya, Kyoto-shi (JP); Hirotaka Nakano, Kyoto-shi (JP)

Correspondence Address: SUGHRUE MION, PLLC, 2100 PENNSYLVANIA AVENUE, N.W., SUITE 800, WASHINGTON, DC, 20037, US

(73) Assignee: ROHM CO., LTD.

(21) Appl. No.: 10/959,246

(22) Filed: Oct. 7, 2004

(30) Foreign Application Priority Data
Oct. 7, 2003 (JP) 2003-348749
Oct. 9, 2003 (JP) 2003-350972
Dec. 19, 2003 (JP) 2003-422353
Mar. 5, 2004 (JP) 2004-061740

(51) Int. Cl. H01L 29/74

(52) U.S. Cl. 257/690

(57) ABSTRACT

There is provided a semiconductor device low in profile, having high heat radiation property, A binding electrode, and draw-out electrodes are formed integrally with the top of an insulting film made out of an aramid non-woven fabric epoxy film, a semiconductor element is attached onto the binding electrode through the intermediary of a solder layer, electrodes provided on the upper surface of the semiconductor element are bonded to the draw-out electrodes by a gold wire, respectively, and all those elements are encapsulated with a synthetic resin. On the other hand, at portions of the insulting film, corresponding to the underside of the binding electrode, and the undersides of the draw-out electrodes, respectively, there is provided an opening having an optional area smaller than that for each of the undersides described, and the draw-out electrodes are bonded to bumps, respectively, through the respective openings, while the lower end face of the binding electrode is exposed to the atmosphere.

### FIELD OF THE INVENTION

The invention relates to a semiconductor device low in profile, having high heat radiation property, and shape stability, and a method of fabricating the same.

### BACKGROUND OF THE INVENTION

A semiconductor device is regarded as one capable of contributing to down-sizing and reduction in thickness of electronic equipment in a very wide variety of fields, such as household appliances, information equipment, transportation equipment including automobiles, and so forth, and as such, advances have been made in development of the semiconductor device toward further down-sizing thereof, along with faster data processing, higher function, and larger capacity.

To give an example, there is known the so-called chip size package (CSP) as a semiconductor package of outer dimensions equivalent to, or slightly larger than those for a semiconductor chip (element). The CSP is completed by forming a multitude of semiconductor chips over a semiconductor wafer, encapsulating the upper part of the semiconductor wafer with a resin, and subsequently, by dicing the semiconductor wafer so as to be divided into individual semiconductor devices.

FIG. 57 is a sectional view showing an example of a conventional semiconductor device according to the conventional CSP. With the semiconductor device, a thermoplastic resin film 81 is adopted for a support substrate for supporting a semiconductor chip, thereby aiming at reduction in thickness of the semiconductor device. With the semiconductor device, there is formed the support substrate made up by thermal compression bonding of electrically conductive foils, to serve as electrodes, to the top and bottom thereof, respectively, with a soft resin or the thermoplastic resin film 81, interposed therebetween, and the electrically conductive foils are etched to thereby form a binding electrode 84, and draw-out electrodes 85, serving as first electrode, while a semiconductor chip 88 is disposed over the binding electrode 84 with an electrically conductive paste 89 interposed therebetween. Further, the respective electrically conductive foils 85, 86 are electrically continuous with each other through an electric conductor 87 disposed so as to penetrate through the thermoplastic resin film 81 when the support substrate is formed integrally with the respective electrically conductive foils 85, 86 by the thermal compression bonding without a via hole penetrating through the film, provided, and the semiconductor chip 88 is bonded to the draw-out electrodes 85 via a conductive wire 91, respectively, all those being encapsulated with an insulating resin 92 (refer to Patent Document 1: JP-2002-176121A).

Further, as a semiconductor device aiming at a low in profile, there is known a semiconductor device in which the support substrate is dispensed with during a fabrication process, that is, one from which the support substrate is stripped. For example, with a semiconductor device shown in FIG. 58, a plurality of terminals 103 are disposed such that outer terminal faces 103c thereof are flush with each other, and a die pad 102 is disposed substantially at the center of an array of the terminals 103 such that the outer terminal faces 103c of the terminals 103 are flush with an outer surface 102c.

A semiconductor chip element 105 is mounted over an inner surface 102b of the die pad 102 such that a side of the semiconductor chip element 105, opposite from an element surface, is bonded to the inner surface 102b with an electrically insulating material 106 interposed therebetween. Terminals 105a of the semiconductor chip element 105 are connected with inner terminal faces 103b of the terminals 103 by a wire 107, respectively, and the terminals 103, the die pad 102, the semiconductor chip element 105, and the wires 107 are encapsulated with a resin member 108 in such a way as to expose the outer terminal faces 103c of the terminals 103, and the outer surface 102c of the die pad 102 to outside. Further, a solder ball 109 is attached to each of the outer terminal faces 103c of the terminals 103 that are exposed to outside.

In fabricating the semiconductor device described, an electrically conductive substrate made of an alloy selected from the group consisting of iron-nickel alloy, iron-nickel-chromium alloy, iron-nickel-carbon alloy, and so forth, or an insulating substrate with a surface provided with an electrically conductive layer made of an element selected from the group consisting of Cu, Ni, Ag, Pd, and Au, or an alloy made of those elements is first used, a resist pattern is formed on the substrate, and subsequently, a metal is deposited on the substrate through the intermediary of the resist pattern, thereby forming a circuitry part comprising the die pad 102 and the plurality of the terminals. The semiconductor chip element 105 is mounted over the die pad 102 as a semiconductor circuitry member with the electrically insulating material 106 interposed therebetween.

Next, the terminals 105a of the semiconductor chip element 105 are connected with the inner terminal faces 103b of the terminals 103 of the semiconductor circuitry member by use of the wire 107, respectively. Thereafter, the terminals, the die pad, the semiconductor chip element 105, and the wires 107 are encapsulated over the electrically conductive substrate by the resin member 108. Subsequently, the semiconductor device encapsulated with the resin is stripped from the electrically conductive substrate, and thereafter, the solder ball 109 is attached to each of the outer terminal faces of the terminals 103, externally exposed.

In fabricating the semiconductor device described, after the semiconductor chip element 105, the wires 107, and so forth, over the electrically conductive substrate (not shown) or the insulating substrate (not shown) with the surface provided with the electrically conductive layer, are encapsulated with the resin, the semiconductor device encapsulated with the resin is stripped from the electrically conductive substrate. In the step of stripping as described, in order to enable the semiconductor device to be stripped with ease, use is made of any of methods, such as execution of a processing for forming asperities on the surface of the electrically conductive substrate by applying a blast processing thereto with the use of a sandblast (1), formation of an oxide film on the surface of the electrically conductive substrate (2), and pre-formation of a soluble metal (for example, copper) face on the substrate by plating, and so forth (3) (refer to Patent Document 2: JP-2002-289739A).

However, with circuit members for the semiconductor device described in Patent Document 1, the support substrate is comprised of the soft resin or the thermoplastic resin film 81, so that there is a problem that the support substrate undergoes deformation in hot working steps including at the time of solder bonding for die bonding between the binding electrode 84, and the semiconductor chip 88, at the time of wire bonding of the draw-out electrode 85, and at the time of the encapsulation with the resin, thereby causing electrode positions to be misaligned on occasions.

Further, as the semiconductor chip 88 makes advances toward higher performance, a heating value thereof increases, and since a second electrode 86 is used as a connection electrode to be soldered to a printed board, and there is the need for disposing the connection electrode so as to stand off form the printed board so that no bridge is formed when the connection electrode is soldered to the printed board, the connection electrode is formed so as to be smaller than the binding electrode corresponding thereto, and the draw-out electrode. That is, the second electrode (connection electrode) under the binding electrode does not match the semiconductor element in size, and while as the semiconductor chip 88 makes advances toward higher performance, the heating value thereof increases, the binding electrode of the semiconductor chip is not in direct contact with the atmosphere, so that there is a problem in that sufficient heat radiation of the semiconductor device cannot be effected when the semiconductor device is mounted on the printed circuit board.

Because the thermoplastic resin film is under constraints in terms of strength, and so forth, the same needs to have a thickness about 50 μm, so that it is difficult to implement further reduction in the thickness of the semiconductor device.

With the semiconductor device described in Patent Document 2, as the support substrate is removed, further reduction in the thickness of the semiconductor device can be implemented, however, since the semiconductor element is mounted over inner terminals with the electrically insulating material 106 interposed therebetween, the semiconductor element has poor heat radiation property as for heat generated therein in the first place, and further, problems from the fabricating point of view exist in that with the method (1) among the above-described methods for stripping the semiconductor device, formed over the electrically conductive substrate and encapsulated with the resin, from the electrically conductive substrate with ease during the process of fabricating semiconductor device, to the contrary, it becomes difficult in practice to peel off a circuitry part from the substrate upon the execution of the processing for forming the asperities on the surface of the electrically conductive substrate, with the method (2), pretreatment to apply an oxidation processing to the surface of the substrate, and with the method (3), not only a plating processing is required, but also it is difficult to dissolve only a copper layer if the electrically conductive substrate is made of a metal, and the copper layer is formed thereon.

Further, as a surface treatment for forming the asperities on a face of the substrate by applying the sandblast processing thereto, and a peel-off treatment for providing the substrate with strippable property by forming the oxide film on the surface of the substrate are applied in order to peel off the semiconductor device, formed over the electrically conductive substrate and encapsulated with the resin, from the conductive substrate with ease, there is a problem that those treatments are troublesome, requiring extra treatment time and cost.

Further, as the semiconductor element described as above is mounted over the inner terminals with the electrically insulating material interposed therebetween, the semiconductor element has poor heat radiation property as for the heat generated therein, and poor strippable property, so that the resin for encapsulation is stripped from the circuitry part by a force applied when stripping the semiconductor device from the electrically conductive substrate, or cracks are prone to occur to the circuitry part. Accordingly, protrusions are formed around the surface of the circuitry part, on a side thereof, opposite from a face of the circuitry part, in contact with the substrate, but the protrusions formed in the lateral direction result in an increase in area, thereby rendering the same unsuitable for a product accommodating a multitude of pins at fine pitches, and in addition, the protrusions in the lateral direction are formed by plating to a plating thickness higher than the height of a thick-film resist, so that there exists a problem that it is difficult to control the area of the protrusions, and difficulty is encountered in fabricating the semiconductor device.

The invention has been developed to resolve those problems encountered by the related art, and it is a first object of the invention to provide a semiconductor device having excellent heat radiation property, and capable of reducing the thickness thereof, insusceptible to the effects of heat generated during a fabricating process and at the time of surface mounting, and easy to fabricate as well as advantageous in terms of cost.

Further, a second object of the invention is to fabricate a semiconductor device swiftly by substituting a chemical process by etching for a mechanical process whereby an electrically conductive foil is press-bonded to a support substrate when forming the support substrate.

Still further, a third object of the invention is to execute stripping in a process of fabricating semiconductor device by use of an easy and simple method and in addition, to enhance strippable property, thereby reducing fabrication process time and cost while further enhancing heat radiation property.

A first aspect of the invention is a semiconductor device characterized in comprising elements including an insulting film, a binding electrode, and draw-out electrodes, formed over the insulting film, on one side thereof, a semiconductor element connected to the top of the binding electrode through the intermediary of an electrically conductive material, wires interconnecting electrodes of the semiconductor element, and the draw-out electrodes, respectively, and an insulating resin encapsulating the elements, wherein a heat radiation sheet for radiating heat of the binding electrode, and solder balls connected with the draw-out electrodes, respectively; are provided on the insulting film, on the other side thereof.

A second aspect of the invention is a semiconductor device according to the first aspect of the invention characterized in that the heat radiation sheet is connected with the binding electrode via an opening through the intermediary of an electrically conductive and thermally conductive substance.

A third aspect of the invention is a semiconductor device according to the first or second aspect of the invention characterized in that the insulting film is made out of an aramid non-woven fabric epoxy.

A fourth aspect of the invention is a semiconductor device characterized in comprising a heat resistant and deformable insulting film, a binding electrode, and draw-out electrodes, formed over the top surface of the insulting film, a semiconductor element connected to the top of the binding electrode through the intermediary of an electrically conductive substance, wires interconnecting electrodes of the semiconductor element, and the draw-out electrodes, respectively, an insulating resin encapsulating the entire top surface side of the insulting film, openings formed in the insulting film, so as to correspond to the back surfaces of the binding electrode, and the draw-out electrodes, respectively, and bumps connected with the draw-out electrodes, respectively, through the respective openings.

A fifth aspect of the invention is a semiconductor device according to the fourth aspect of the invention characterized in that the insulting film is made out of an aramid non-woven fabric epoxy film.

A sixth aspect of the invention is a semiconductor device characterized in comprising a semiconductor element, a binding electrode connected to the semiconductor element through the intermediary of an electrically conductive substance, doubling as a heat radiation sheet, and draw-out electrodes, and an insulating resin encapsulating the top surface side of the semiconductor element, the binding electrode doubling as the heat radiation sheet, and the draw-out electrodes, so as not to be exposed to the atmosphere, while exposing the back surface side of the binding electrode doubling as the heat radiation sheet, and the draw-out electrodes, to the atmosphere, wherein the binding electrode, doubling as the heat radiation sheet, has a heat radiation region located outside of a region of the semiconductor element in a plan view when the semiconductor element is disposed over the binding electrode.

A seventh aspect of the invention is a semiconductor device characterized in comprising elements including an insulting film, a binding electrode, and draw-out electrodes, provided, on one face side of the insulting film, a semiconductor element disposed over the binding electrode through the intermediary of an electrically conductive layer formed on the binding electrode, wires interconnecting electrodes of the semiconductor element, and the draw-out electrodes, respectively, an insulating resin encapsulating the elements, and connection electrodes and a heat radiation sheet, provided on the other face side of the insulting film, so as to correspond to the draw-out electrodes and the binding electrode, respectively, wherein at least one pair comprised of the binding electrode, and the heat radiation sheet or one of the draw-out electrodes and one of the connection electrodes has a through-hole penetrating through the insulting film, thereby being connected with each other through the intermediary of an electrically conductive material filled in the through-hole.

An eighth aspect of the invention is a semiconductor device according to the seventh aspect of the invention characterized in that the electrically conductive material filled in the through-hole is composed mainly of substance of the electrically conductive layer for securely holding the binding electrode, and the semiconductor element together, and or substance for forming solder bumps.

A ninth aspect of the invention is a method of fabricating a semiconductor device characterized in comprising the steps of forming a binding electrode, and draw-out electrodes, by etching an electrode material provided over a heat resistant and deformable insulting film, providing openings in the insulting film, so as to correspond to the back surface side of the binding electrode, and the draw-out electrodes, respectively, connecting a semiconductor element onto the binding electrode through the intermediary of an electrically conductive substance, bonding electrodes of the semiconductor element, to the draw-out electrodes, respectively, encapsulating the entire surface of the insulting film, on the side of the semiconductor element, with an insulating resin, and connecting the draw-out electrodes with bumps, via the openings, respectively.

A tenth aspect of the invention is a method of fabricating a semiconductor device according to the ninth aspect of the invention characterized in that the insulting film is made out of an aramid non-woven fabric epoxy film.

An eleventh aspect of the invention is a method of fabricating a semiconductor device characterized in comprising the steps of forming a binding electrode doubling as a heat radiation sheet, and draw-out electrodes over a support substrate, connecting a semiconductor element onto the binding electrode over the support substrate, doubling as the heat radiation sheet, through the intermediary of an electrically conductive substance, bonding electrodes of the semiconductor element, to the draw-out electrodes, respectively, encapsulating the semiconductor element, the binding electrode doubling as the heat radiation sheet, the draw-out electrodes, provided over the support substrate, with an insulating resin, and stripping the support substrate from the interfaces thereof, with the back surface of the binding electrode doubling as the heat radiation sheet, the respective back surfaces of the draw-out electrodes, and the insulating resin, thereby exposing the respective back surface sides of the binding electrode doubling as the heat radiation sheet and the draw-out electrodes, wherein the step of forming the binding electrode doubling as the heat radiation sheet is the step of forming the binding electrode such that the binding electrode, has a heat radiation region located outside of a region of the semiconductor element in a plan view when the semiconductor element is disposed over the binding electrode.

A twelfth aspect of the invention is a method of fabricating a semiconductor device according to the eleventh aspect of the invention characterized in that the support substrate is made out of stainless steel, and the binding electrode doubling as the heat radiation sheet, and the draw-out electrodes are formed by a plating method.

A thirteenth aspect of the invention is a method of fabricating a semiconductor device according to the eleventh aspect of the invention characterized in that the step of stripping the support substrate from the interfaces thereof, with the back surface of the binding electrode doubling as the heat radiation sheet, the respective back surfaces of the draw-out electrodes, and the insulating resin, thereby exposing the respective back surface sides of the binding electrode doubling as the heat radiation sheet and the draw-out electrodes is the step of stripping an adhesive film formed on the support substrate, and the support substrate from, the interfaces thereof, with the back surface of the binding electrode doubling as the heat radiation sheet, the respective back surfaces of the draw-out electrodes, and the insulating resin, thereby exposing the respective back surface sides of the binding electrode doubling as the heat radiation sheet and the draw-out electrodes.

A fourteenth aspect of the invention is a method of fabricating a semiconductor device according to the eleventh or thirteenth aspect of the invention characterized in that the support substrate is formed of glass epoxy resin and the adhesive film is formed of a silicon resin.

The semiconductor device according to the invention has the following advantageous effects.

Hest radiation can be effected through the heat radiation sheet exposed to the atmosphere at a portion of the insulting film, on the back surface side thereof, corresponding to the underside of the binding electrode, and since the heat radiation sheet has flexibility in respect of size, it is possible to provide the heat radiation sheet of a size corresponding to a high-performance semiconductor device having a high heating value. Or radiation of the hest generated in the semiconductor element can be effected from the heat radiation region as well when the semiconductor element is disposed (mounted) over the binding electrode, in addition to from a region on the underside of the semiconductor element, so that the semiconductor device has quite excellent heat radiation efficiency. Further, with adoption of a configuration where the binding electrode, and the draw-out electrodes are exposed to the atmosphere, it has high heat radiation property. Furthermore, due to high heat radiation property thereof, it is possible to package a higher-integrated, and higher-performance semiconductor chip (element).

Because the binding electrode, and the draw-out electrodes are formed over the insulting film, the semiconductor device can be reduced in thickness, and in particular, in the case of using an aramid non-woven fabric epoxy resin film, the support substrate made out of the aramid non-woven fabric epoxy film, for example, even about 70 μm in thickness, equivalent to about half the thickness of a conventional support substrate, can exhibit the same function as the conventional one, so that it is possible to reduce the thickness as small as, for example, 10 μm. Accordingly, by use of such a support substrate as the insulting film, the semiconductor device low in profile can be provided.

Since the binding electrode, the draw-out electrodes, and the heat radiation sheet are formed by simultaneously etching the copper foils on both sides, it is possible to fabricate the semiconductor device in short time, and to reduce the fabrication cost thereof.

Further, if stainless steel is used for the support substrate, mold-releasability is improved when stripping the semiconductor device from the support substrate, so that stripping can be easily executed without a particular strip processing as required in the past, thereby enabling fabrication time, and cost to be reduced.

Furthermore, with a simple operation of providing the support substrate with a mold-releasing adhesive layer for improving mold-releasability, a strip processing can be executed with ease. Particularly, in the case of using a glass epoxy resin for the support substrate, use of a silicon resin as a mold-releasing adhesive will further facilitate stripping from the support substrate because of permeation of the silicon resin into glass fiber. Accordingly, a mold-releasing processing as required in the past is no longer required, thereby enabling time and cost required for such a processing to be eliminated.

The binding electrode, the heat radiation sheet, and the insulting film are integrally and strongly bonded with each other by connecting the binding electrode with the heat radiation sheet through the intermediary of the electrically conductive material filled in the respective through-holes, so that there is no risk of the binding electrode, the draw-out electrodes, the insulating resin for encapsulation, on one face side of the insulting film, as well as the heat radiation sheet, and the connection electrodes, on the other face side of the insulting film, being stripped from the insulting film. Further, with the configuration described, since the hest generated in the semiconductor element is conducted to the heat radiation sheet, on the back surface side of the insulting film, through the intermediary of the electrically conductive material such as the high melting point solder layer or the through-hole copper plating film, and so forth, in the respective through-holes, high heat radiation property can be gained.

Still further, as it is possible to laminate the copper foils to both the side faces of the insulting film, respectively, and to bore the through-holes by a drill or a press, and so forth, the fabrication cost can be considerably reduced. Further, since the binding electrode, and the draw-out electrodes are formed by etching the copper foil over the insulting film, it is possible to implement fabrication in short time and at a low cost as compared with the case of the conventional mechanical process by use of thermal compression bonding.

Now, since the aramid non-woven fabric epoxy film is obtained by impregnating a heat resistant aramid non-woven fabric with a thermosetting epoxy resin, the aramid non-woven fabric epoxy film remains stable in shape during process steps affected by heat at the time of fabrication or at the time of mounting, so that it has an advantage of precluding the risk of electrode positions being misaligned besides being low in cost. In addition, since the aramid non-woven fabric is excellent in membrane strength, the support substrate, and consequently, the semiconductor device can be reduced in thickness.

### BREIF DESCRIPTION OF THE DRAWINGS

FIG. 1 is a sectional view of a first embodiment of a semiconductor device according to the invention;

FIGS. 2A and 2B are views, showing a second embodiment of a semiconductor device according to the invention, in which FIG. 2A is a sectional view of the semiconductor device, and FIG. 2B is a plan view thereof;

FIG. 3 is a sectional view of a copper-laminated sheet for use in carrying out the invention;

FIG. 4 is a sectional view of a workpiece obtained by a process step for lamination of dry film resists of a method of fabricating the semiconductor device according to the invention;

FIG. 5 is a sectional view of a workpiece obtained by a development process step of the method of fabricating the semiconductor device according to the invention;

FIGS. 6A and 6B are schematic views, showing a workpiece obtained by a stripping process step, in which FIG. 6A is a sectional view thereof and FIG. 6B is a plan view thereof;

FIG. 7 is a sectional view of a workpiece obtained by a boring process step;

FIG. 8 is a sectional view of a workpiece obtained by a plating process step;

FIG. 9 is a sectional view of a workpiece obtained by a wire bonding process step;

FIG. 10 is a sectional view of a workpiece obtained by a resin molding process step;

FIG. 11 is a sectional view of a workpiece obtained by a process step for forming solder bumps, and so forth;

FIG. 12 is a schematic view of a workpiece obtained by a stripping process step of a method of fabricating another semiconductor device according to the invention;

FIG. 13 is a sectional view of a semiconductor device obtained by another embodiment of a method of fabricating a semiconductor device according to the invention;

FIG. 14 is a sectional view of a third embodiment of a semiconductor device according to the invention;

FIGS. 15A and 15B are sectional views, showing a workpiece obtained by a process step for fabrication of a copper-laminated sheet in which FIG. 15A is a sectional view thereof, and FIG. 15B is a plan view thereof;

FIGS. 16A and 16B are sectional views of a workpiece obtained by a development process step;

FIGS. 17A and 17B are schematic views, showing a workpiece obtained by a stripping process step, in which FIG. 17A is a sectional view thereof, and FIG. 17B is a plan view thereof;

FIG. 18 is a sectional view of a workpiece workpiece obtained by a boring process step;

FIG. 19 is a sectional view of a workpiece obtained by a plating process step;

FIG. 20 is a sectional view of a workpiece obtained by a wire bonding process step;

FIG. 21 is a sectional view of a workpiece obtained by a resin molding process step;

FIG. 22 is a sectional view of a workpiece obtained by a process step for forming bumps on respective draw-out electrodes;

FIG. 23 is a sectional view of a fourth embodiment of a semiconductor device according to the invention;

FIGS. 24A and 24B are views, showing a fifth embodiment of a semiconductor device according to the invention, in which FIG. 24A is a sectional view thereof, and FIG. 24B is a plan view thereof;

FIG. 25 is a sectional view of a sixth embodiment of a semiconductor device according to the invention;

FIG. 26 is a sectional view of a seventh embodiment of a semiconductor device according to the invention;

FIG. 27 is a sectional view of a workpiece obtained by a development process step;

FIG. 28 is a sectional view of a workpiece obtained by a plating process step:

FIGS. 29A and 29B schematic views, showing a workpiece obtained by a stripping process step, in which FIG. 29A is a sectional view thereof, and FIG. 29B is a plan view thereof;

FIG. 30 is a sectional view of a workpiece obtained by a wire bonding process step;

FIG. 31 is a sectional view of a workpiece obtained by a resin molding process step;

FIG. 32 is a sectional view of a workpiece obtained by a process step for stripping from a support substrate;

FIG. 33 is a sectional view of a workpiece obtained by a process step for forming bumps;

FIG. 34 is a sectional view of a workpiece obtained by a process step for lamination of a dry film resist in a method of fabricating a semiconductor device according to an eighth embodiment of the invention;

FIG. 35 is a sectional view of a workpiece obtained by an etching process step;

FIG. 36 is a sectional view of a workpiece obtained by a process step for formation of a plating film;

FIGS. 37A and 37B are schematic views, showing a semiconductor device according to a ninth embodiment of invention, in which FIG. 37A is a sectional view thereof, and FIG. 37B is a plan view thereof;

FIG. 38 is a sectional view of a tenth embodiment of a semiconductor device according to the invention;

FIG. 39 is a sectional view of an eleventh embodiment of a semiconductor device according to the invention;

FIG. 40 is a sectional view of a twelfth embodiment of a semiconductor device according to the invention;

FIG. 41 is a sectional view of a thirteenth embodiment of a semiconductor device according to the invention;

FIGS. 42A and 42B are schematic views, showing a semiconductor device according to a fourteenth embodiment of invention, in which FIG. 42A is a sectional view thereof, and FIG. 42B is a plan view thereof;

FIG. 43 is a sectional view showing a construction of a copper-laminated sheet for use in carrying out the ninth embodiment of a method of fabricating a semiconductor device according to the invention;

FIG. 44 is a sectional view of a workpiece obtained by a boring process step:

FIG. 45 is a sectional view of a workpiece obtained by a process step for lamination of dry film resists;

FIG. 46 is a sectional view of a workpiece obtained by a development process step;

FIG. 47 is a sectional view of a workpiece obtained by a stripping process step after an etching process step;

FIG. 48 is a sectional view of a workpiece obtained by a plating process step;

FIG. 49 is a sectional view of a workpiece obtained by a process step for die bonding, and blocking through-holes in respective draw-out electrodes;

FIG. 50 is a sectional view of a workpiece obtained by a wire bonding process step;

FIG. 51 is a sectional view of a workpiece obtained by a resin molding process step;

FIG. 52 is a sectional view of a workpiece obtained by a process step for forming solder bumps;

FIG. 53 is a schematic view for describing in detail a process step for formation of through-hole copper plating film as one of the process steps of a method of fabricating the semiconductor device according to the twelfth embodiment of the invention, showing a sectional view of a support substrate as prepared;

FIG. 54 is an enlarged sectional view showing a state where the support substrate shown in FIG. 53 is immersed in a solution of a carbon treatment agent, thereby causing carbon black to adsorb on the entire surface of the support substrate;

FIG. 55 is an enlarged sectional view showing a state where the support substrate with the carbon black adsorbing on the entire surface thereof, as shown in FIG. 54, is etched, thereby causing the carbon black to be left out only on the end faces of the insulting film, in a through-hole;

FIG. 56 is an enlarged sectional view showing a state where copper electroplating is applied to the support substrate with the carbon black left out only on the end faces of the insulting film, thereby forming a through-hole copper plating film inside the through-hole;

FIG. 57 is a sectional view of a conventional semiconductor device; and

FIG. 57 is a sectional view of another conventional semiconductor device.

### PREFERRED EMBODIMENTS OF THE INVENTION

Embodiments of a semiconductor device according to the invention are described hereinafter with reference to the accompanying drawings.

First Embodiment

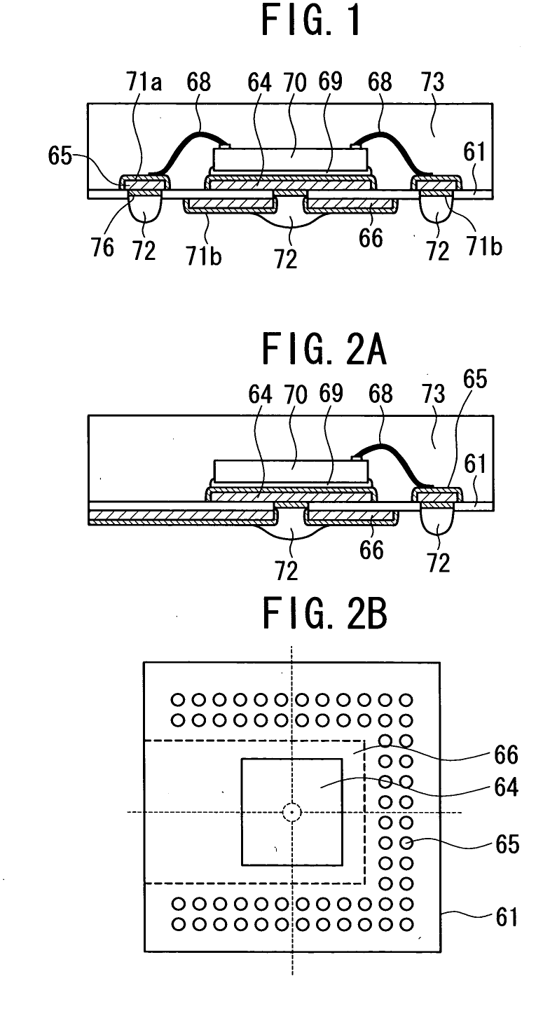

FIG. 1 is a sectional view of a first embodiment of a semiconductor device according to the invention. The semiconductor device comprises a binding electrode 64 formed by etching a copper foil formed over an insulting film 61 made out of, for example, an aramid non-woven fabric epoxy film, and a plurality of draw-out electrodes 65 formed out of a copper foil similarly to the binding electrode 64 in such a way as to surround the binding electrode 64, and a plating layer capable of soldering and wire bonding by gold, for example, a nickel-gold film is formed over the binding electrode 64, and the draw-out electrodes 65 while a semiconductor element 70 is attached onto the top of the nickel-gold film over the binding electrode 64 through the intermediary of a high melting point solder 69. Further, electrodes on top of the semiconductor element 70 are connected with the draw-out electrodes 65 by a gold wire 68, respectively. As shown in the figure, respective elements over the insulting film are encapsulated with an epoxy resin 73.

A heat radiation sheet 66 formed out of a copper foil similarly to the case of the binding electrode 64, for radiating heat generated in the semiconductor element 70, is provided in a region of the insulting film 61, on a side thereof, opposite from the semiconductor element 70, corresponding to the binding electrode 64.

Further, an opening 76 is formed in portions of the insulting film 61, provided with the binding electrode 64 and the respective draw-out electrodes 65, respectively, and a nickel-gold film 71b is formed on the back surface of the heat radiation sheet 66, and the back surface of a portion of the binding electrode 64 as well as the respective back surfaces of portions of the draw-out electrodes 65, exposed to the respective openings, respectively.

A solder ball 72 made of a Pb-free solder composed of, for example, Sn, Cu, and Ag for connecting a circuitry in a printed board with the binding electrode 64 and the draw-out electrodes 65, respectively, is attached to the respective openings 76 when the semiconductor device is mounted on the printed board. Further, the heat radiation sheet 66 is connected with the binding electrode 64 through metallic bond through the intermediary of the solder ball 72 attached to the opening, and the nickel-gold film 71b.

With a configuration described as above, the heat generated in the semiconductor element 70 is conducted to the heat radiation sheet 66 via the high melting point solder layer 69, the binding electrode 64, the nickel-gold film 71b, and the solder ball 72, thereby effecting excellent heat radiation.

FIGS. 2A and 2B are views each showing a second embodiment of a semiconductor device according to the invention, in which FIG. 2A is a sectional view of the semiconductor device, and FIG. 2B is a plan view thereof.

As shown in FIGS. 2A and 2B, with the semiconductor device according to the second embodiment, a plurality of draw-out electrodes 65 are disposed around a binding electrode 64 except for in a region of an insulting film 61, on one side (in the figure, toward the left-hand side) thereof, which is left vacant without any of the draw-out electrodes 65 being provided, and a heat radiation sheet 66 is provided on the entire surface of a portion of the insulting film 61, on a side thereof, opposite from the region.

With the present embodiment, since the heat radiation sheet 66 is larger in area than the heat radiation sheet 66 of the semiconductor device according to the first embodiment, shown in FIG. 1, the function of the heat radiation sheet 66 serving as a heat sink is enhanced along with an increase in area of the heat radiation sheet 66, in contact with a circuit board, so that the semiconductor device according to the present embodiment has more excellent heat radiation property.

Now, a method of fabricating the semiconductor device according to the invention is described hereinafter.

(1) Process Step for Fabrication of a Copper-Laminated Sheet:

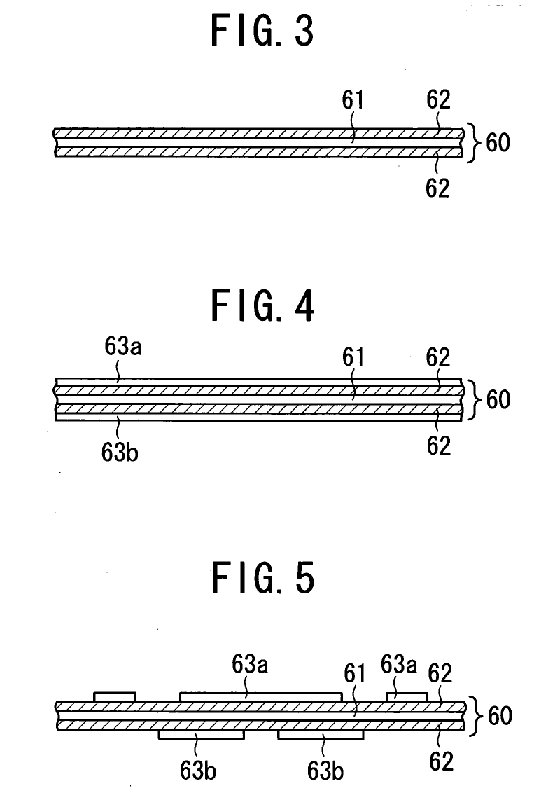

FIG. 3 is a sectional view showing a construction of a copper-laminated sheet for use in carrying out the invention. As shown in FIG. 3, use is made of the copper-laminated sheet 60 formed by laminating two layers of copper foils 62, 62 to the top and underside of the insulting film 61 made out of, for example, the aramid non-woven fabric epoxy film, respectively. In this connection, the aramid non-woven fabric epoxy film is obtained by impregnating an aramid non-woven fabric with an epoxy resin, and subsequently, reducing the aramid non-woven fabric into a film-like state by applying hot pressing thereto. The aramid non-woven fabric epoxy film is, for example, 50 μm in film thickness, and use is made of the copper foils 62, 62, for example, made out of electrolytic copper foils 18 μm in thickness, respectively.

There has been seen a tendency of the aramid non-woven fabric epoxy film becoming thinner in thickness, including one even as thins as 1.5 μm.

(2) Process Step for Lamination of Dry Film Resists:

Dry film resists 63a, 63b are laminated to the copper-laminated sheet 60 as prepared from the top side and underside side thereof, respectively, with the use of a lamination apparatus. FIG. 4 is a sectional view of a workpiece obtained by this process step.

For the dry film resists to be used in the process, use is made of a dry film resist, for example, 6 μm in thickness, and for the lamination apparatus, use is made of a hot roll laminator. The lamination process is applied with lamination temperature at 50° C., lamination rate at 1.5 m/min, and air cylinder pressure at 0,4 MPa, carrying out aging for retaining room temperature for one hour after lamination.

(3) Exposure Process Step:

In the present process step, exposure is applied to the dry film resists using negative masks having desired patterns, respectively, from the top side and bottom side of the negative masks, respectively. For an optical aligner to be used in this process, use is made of, for example, a parallel light beam aligner, wherein an exposure method as adopted is the proximity exposure method, and an exposure quantity is 80 mJ/cm².

(4) Development Process Step:

The workpiece after completion of the exposure process step is developed by use of a conveyer type spray developer. A developing solution for use is a solution of 1% sodium carbonate, and the workpiece is developed in the solution at 30° C. for 200 seconds to be subsequently washed in water, and dried before discharged from a conveyer as a developed product.

FIG. 5 is a sectional view of a workpiece in a state where the development process step has been completed. As shown in the figure, the dry film resists 63a, 63b, having desired patterns, respectively, are formed on the copper foils 62, 62, respectively.

(5) Etching Process Step:

In the present process step, the workpiece after completion of the development process step is etched by use of a conveyer-spray type etching system. More specifically, the workpiece after development is immersed in an etchant (at 50C) with iron (III) chloride as the main constituent, containing about 0.3% hydrochloric acid, for about two minutes. By so doing, respective portions of the copper foil, not covered by the dry film resists 63a, 63b, are etched, leaving out respective other portions of the copper foil, underneath the dry film resists 63a, 63b. Subsequently, the workpiece is passed through a cell with a 5% hydrochloric acid solution kept at room temperature to be thereafter washed in water and dried.

(6) Stripping Process Step:

In the present process step, the dry film resists 63a, 63b are stripped from the insulting film 61, respectively. More specifically, use is made of a remover containing 3% caustic soda kept at 60° C., in which the workpiece after etching is immersed for 80 seconds, thereby stripping the dry film resists 63a, 63b from the insulting film 61, respectively.

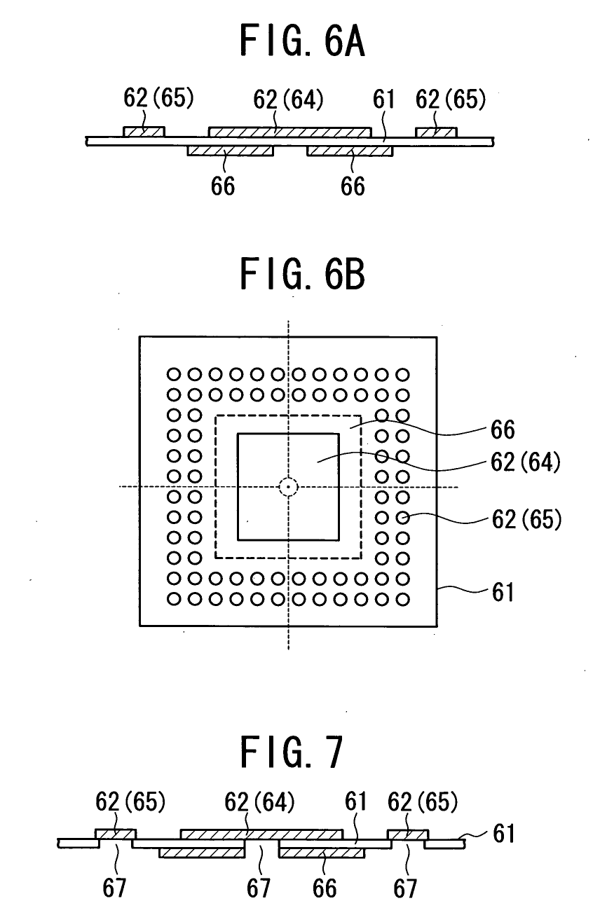

FIG. 6A is a sectional view of the workpiece after stripping as described above. As shown in the figure, the binding electrode 64 and the draw-out electrodes 65, made out of the copper foil 62, are formed on one side of the insulting film 61, and the heat radiation sheet 66 is formed on the other side of the insulting film 61. FIG. 6B is an example of a plan view corresponding to FIG. 6A, and as is evident from the figure, a multitude of the draw-out electrodes 65 are provided in such a way as to surround the periphery of the binding electrode 64.

(7) Process Step of Forming Openings with a Laser (Boring Process Step):

Openings 67 are formed by evaporation of portions of the insulting film 61, at desired positions underneath the draw-out electrodes 65, and the binding electrode 64, formed as described above, respectively, up to a face of the copper foil with the use of, for example, a carbon dioxide gas laser.

FIG. 7 is a sectional view of a workpiece provided with the openings 67. The carbon dioxide gas laser causes desired portions of the insulting film 61 to undergo evaporation, and the openings 67 are shut off with the face of the copper foil.

(8) Plating Process Step:

In the present process step, a plating film comprised of, for example, a nickel film 4 μm thick, and a gold film 0.5 μm thick is formed on the copper foil 62 provided on both sides of the insulting film 61, respectively. For a method of forming the plating film, use is made of, for example, an electroless plating method. In forming the plating film, degreasing is first carried out and subsequently, soft etching with sodium peroxosulfate is applied to the respective surfaces of the copper foils 62. Subsequently, smut is removed in dilute sulfuric acid, the workpiece is pre-dipped in dilute hydrochloric acid after being washing in water, and then, activation processing is applied thereto before being post-dipped in dilute hydrochloric acid. Thereafter, an electroless nickel plating at 80° C. is applied for 10 minutes, thereby forming a nickel plating film about 4 μm thick. After washing the workpiece in water, activation processing in dilute sulfuric acid is applied thereto, and further, displacement gold plating is applied thereto. After the displacement gold plating, the workpiece is washed in water, and gold plating is applied thereto in a gold neutral plating bath at 60° C. for 20 or 30 minutes, thereby forming a gold plating film 0.5 μm thick. Subsequently, the workpiece is washed in water, and dried.

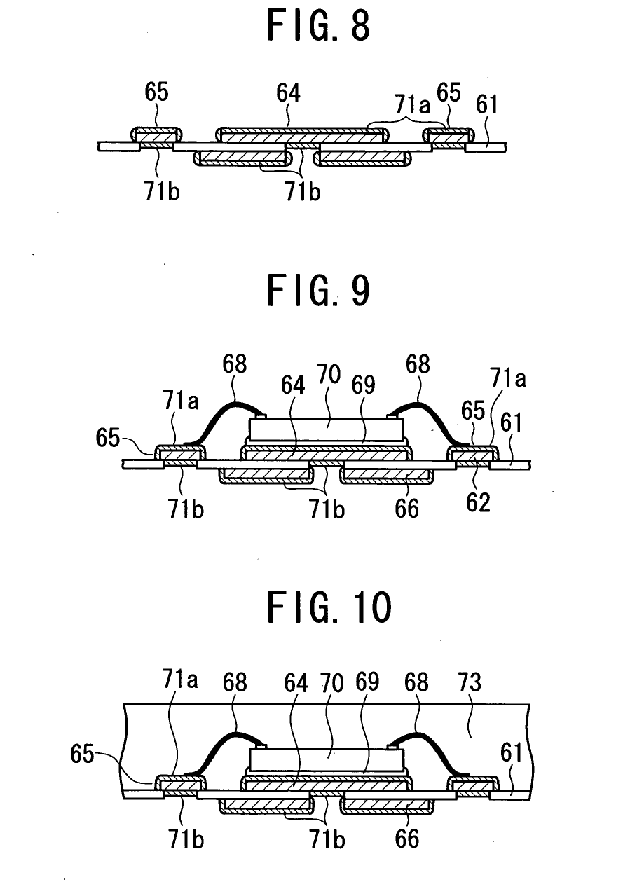

FIG. 8 is a sectional view of a workpiece after the plating process step as described above. As shown in the figure, nickel-gold films 71a, 71b are formed on the copper foils 62 provided on both sides of the insulting film 61, respectively. In this case, a portion of the copper foil 62, at a position underneath the semiconductor element 70, together with the nickel-gold film 71a disposed on top of the portion of the copper foil 62, is referred to as the binding electrode 64.

(9) Die Bonding Process Step:

In the present process step, die bonding of the semiconductor element 70 is implemented by use of the high melting point solder layer 69. In this case, use is made of an Sn—Pb (for example, 10% Sn, and 90% Pb) based solder layer 69 with a high melting point, which is heated to a temperature (for example, 300° C.) not lower than the melting point thereof, thereby mounting the semiconductor element 70 over the binding electrode 64 with the solder layer 69 interposed therebetween.

(10) Wire Bonding Process Step:

Pad electrodes on top of the semiconductor element 70 are bonded to the draw-out electrodes 65 by the gold wire 68, respectively. In this case, portions of the copper foil 62, at positions where wire bonding is implemented, together with the nickel-gold film 71a disposed on top of the respective portions of the copper foil 62, are referred to as the draw-out electrodes 65.

For a method of the wire bonding, use is made of, for example, the thermo-sonic wire bonding method. More specifically, by causing an ultrasonic wave to act on the gold wires 68 for example, 30 μm in diameter in a temperature range of 150 to 250° C. (for example, at 230° C.), thereby bonding the respective gold wires 68 to the pad electrodes and the draw-out electrodes 65, respectively.

FIG. 9 is a sectional view of a workpiece after the wire bonding is implemented.

(11) Resin Molding Process Step:

In the present process step, a circuit-forming surface in whole is encapsulated with resin. More specifically, as shown in FIG. 10, the circuit-forming surface in whole is encapsulated with an insulating resin 73 by a printing method or a transfer molding method. The resin used is the epoxy resin 73 for use in encapsulation of semiconductor, and in the case of the printing method, vacuum de-aeration (at a degree of vacuum of, for example, 10⁻³ Torr) is applied thereto before carrying out printing to a uniform thickness with the use of a squeegee. After the printing, curing at a temperature in a range of 125 to 150° C. is carried out, thereby solidifying the epoxy resin 73. In the case of the transfer molding method, transfer molding is carried out at a temperature in a range of 150 to 180° C., and subsequently, curing at a temperature in a range of 130 to 180° C. is carried out, thereby solidifying the epoxy resin 73.

(12) Process Step for Connecting the Binding Electrode with the Heat Radiation Sheet, and Forming Solder Bumps:

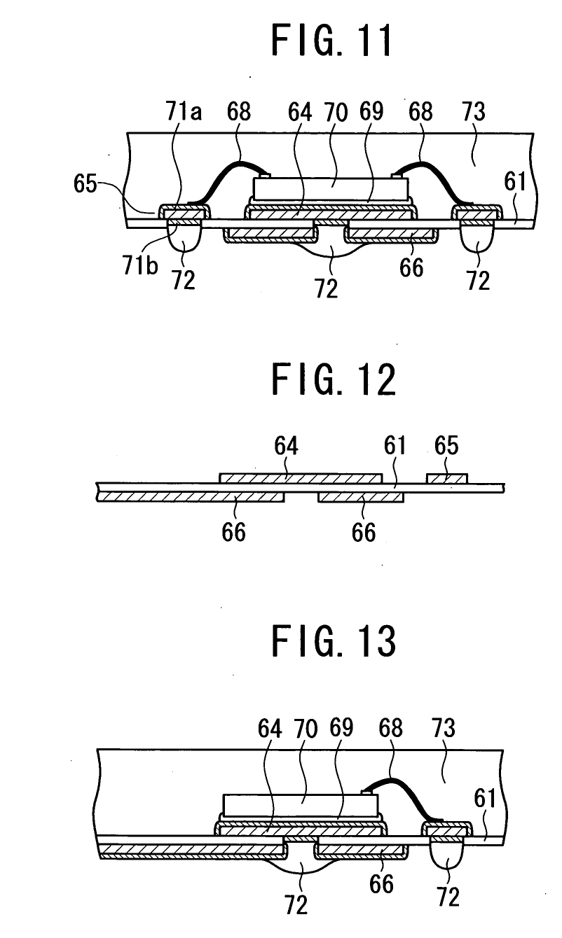

As shown in FIG. 11, the binding electrode 64 is connected with the heat radiation sheet 66 by soldering with the nickel-gold film 71b interposed therebetween, simultaneously forming the solder ball 72 on the nickel-gold films 71b formed underneath the respective draw-out electrodes 65. Solder material containing Pb may be used, however, with the present embodiment, use is made of a Pb-free solder with composition of Sn-3% Cu-0.5% Ag.

Connection by soldering, and formation of the solder balls 72 are implemented as follows. That is, solder balls are adsorbed to a jig in a vacuum, and are disposed at predetermined positions of the openings 67 corresponding to the binding electrode 64 and the draw-out electrodes 65, respectively. Subsequently, reflow is carried out on conditions of 260° C., and 10 minutes. In the reflow process, the metallic bond of the binding electrode 64 to the heat radiation sheet 66 is effected through the intermediary of the nickel-gold film 71b, and solder, and the solder balls 72 are formed so as to be connected with the draw-out electrodes 65, respectively. The heat generated in the semiconductor element 70 is conducted through metal conductors to be thereby radiated to outside with ease from the heat radiation sheet 66.

(13) Dicing Process Step:

Finally, a plurality of the semiconductor devices formed as described above, over a support substrate, are diced into individual semiconductor devices by the unit of the one shown in FIG. 1, thereby obtaining the semiconductor device.

Second Embodiment

With a second embodiment of a method of fabricating a semiconductor device according to the invention, a heat radiation sheet is extended in order to enhance heat radiation property.

That is, the heat radiation sheet 66 may be not only formed at a position directly underneath the binding electrode 64 of the semiconductor element 70 as with a fabrication process according to the first embodiment, but also formed in such a way as to be extended to the left-hand side in the figure as shown inn FIG. 12. FIG. 13 is a sectional view of the semiconductor device fabricated by a fabrication process according to the second embodiment, and on the whole, a method of fabricating the semiconductor device according to the second embodiment is the same as that according to the first embodiment. With this configuration, the heat radiation sheet 66 is larger in area than that in the case of the first embodiment, so that heat radiation effect is further enhanced.

Further, with the embodiments of the invention, shown in FIGS. 1, 2A, 11, and so forth, respectively, the nickel-gold film is shown to cover the entire surface of the heat radiation sheet 66, however, the nickel-gold film may be formed only at parts to which the solder balls 72 are connected, respectively, using a mask at the time of plating while solder plating may be applied to other parts.

Furthermore, a case where the insulting film is made out of the aramid non-woven fabric epoxy film is described in detail, however, the insulting film may be made of a polyimide.

Now, a third embodiment of the invention is described hereinafter.

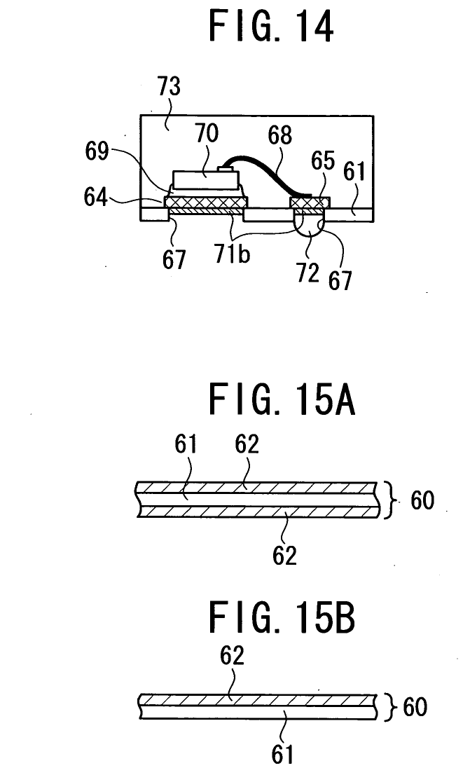

FIG. 14 is a sectional view broadly showing a third embodiment of a semiconductor device according to the invention. The present semiconductor device comprises a binding electrode 64, and draw-out electrodes 65, formed integrally with the top of an insulting film 61 made out of an aramid non-woven fabric epoxy film, and a semiconductor element 70 attached to the insulting film 61 through the intermediary of a high melting point solder layer 69, disposed on top of the binding electrode 64, wherein electrodes provided on the upper surface of the semiconductor element 70 are bonded to the draw-out electrodes 65 by a gold wire 68, respectively. The face of the insulting film, on a side thereof, facing the semiconductor element, that is, the upper face thereof, shown in the figure, is entirely resin-encapsulated with a synthetic resin 73 for protection. Further, at portions of the insulting film 61, corresponding to the underside of the binding electrode 64, and the undersides of the draw-out electrodes 65, respectively, there is provided an opening 67 having an optional area smaller than that for each of the undersides described, and the draw-out electrodes 65 are bonded to bumps 72, respectively, through the respective openings 67, while the lower end face of the binding electrode 64 is exposed to the atmosphere via the opening 67.

With the semiconductor device according to the present embodiment, the insulting film is made out of the aramid non-woven fabric epoxy film. The reason why the aramid non-woven fabric epoxy film is adopted for the insulting film constituting a substrate of the present embodiment is because an epoxy resin is thermosetting in addition to high plane strength of the aramid non-woven fabric, and low cost thereof. In other words, this is because the semiconductor device can be reduced in thickness more than a case of using other kinds of resin since the plane strength is high, and further, it is possible to preclude the risk of misalignment of electrode positions occurring due to heat generated in the soldering process, and so forth, at the time of fabrication or mounting of the semiconductor device because the epoxy resin is thermosetting.

In addition, as the binding electrode 64 is provided with the opening 67, through which the binding electrode 64 is in direct contact with the atmosphere, heat generated in the semiconductor element 70 can be efficiently radiated to outside air.

A third embodiment of a method of fabricating a semiconductor device according to the invention is described by way of example with reference to the accompanying drawings. The method of fabricating the semiconductor device according to the present embodiment comprises process steps (1) to (12) as described hereinafter.

That is,

(1) Process Step for Fabrication of a Copper-Laminated Sheet:

The present process step for fabrication of the copper-laminated sheet is the same as the process step for fabrication of the copper-laminated sheet of the previously-described method of fabricating the semiconductor device according to the first embodiment, and a configuration shown in FIG. 15A is the same as that shown in FIG. 3, however, use may be made of a copper-laminated sheet 60 formed by laminating one layer of copper foil 62 to the top of the insulting film, as shown in FIG. 15B, in place of a copper-laminated sheet 60 provided with two layers of copper foils 62, 62, configured as shown in FIG. 15A.

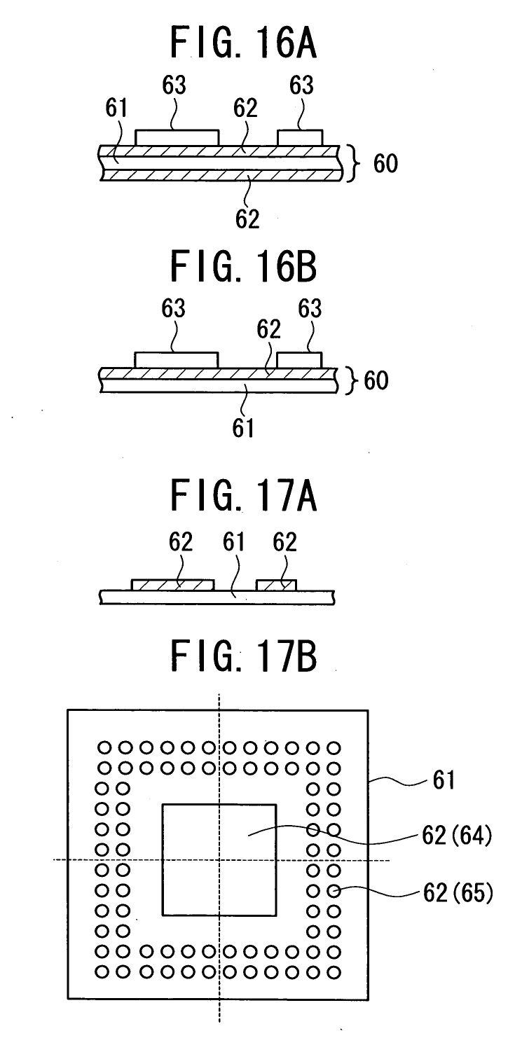

A process step for lamination of a dry film resist (2) subsequent to the process step for the fabrication of the copper-laminated sheet (1), an exposure process step (3), a development process step (4), an etching process step (5), and a stripping process step (6) are the same as those corresponding thereto, respectively, of the method of fabricating the semiconductor device according to the first embodiment. FIGS. 16A and 16B are sectional views showing a workpiece obtained after the development process step, respectively, that is, the copper-laminated sheet 60 with a dry film resist 63 having a pattern, formed on the copper foil 62, respectively. FIG. 17A is a sectional view of a workpiece obtained by the stripping process step, and 17B is an example of a plan view thereof, FIGS. 17A, 17B corresponding to FIGS. 6A, 6B, respectively. As shown in the figures, in the stripping process step, a copper foil pattern as desired is formed on the insulting film.

(7) Process Step of Forming Openings with a Laser (Boring Process Step)

In the present process step, the opening 67 is formed in portions of the insulting film 61, at positions underneath the respective copper foils by use of, for example, the carbon dioxide gas laser. The carbon dioxide gas laser causes the portions of the insulting film to undergo evaporation up to a face of each of the copper foils, and in this case, there are formed the openings 67 slightly smaller than the respective copper foils as patterned

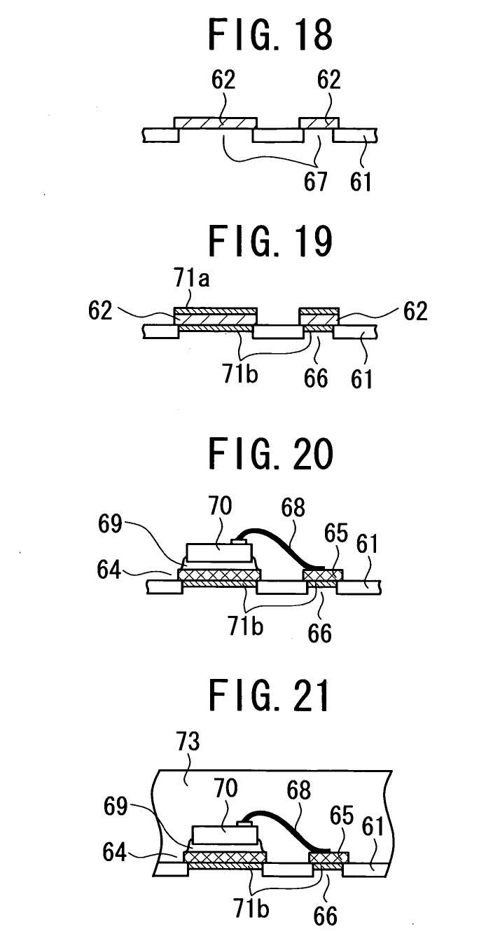

FIG. 18 is a sectional view of a workpiece after the boring process step.

(8) Plating Process Step:

The present process step also is the same as the plating process step of the method of fabricating the semiconductor device according to the first embodiment. FIG. 19 is a sectional view of a workpiece formed by the plating process step, showing that nickel-gold films 71a, 71b are formed on the upper side, and underside of the respective copper foils 62, respectively. A die bonding process step (9) subsequent to the plating process step, a wire bonding process step (10), and a resin molding process step (11) are the same as those corresponding thereto, respectively, of the method of fabricating the semiconductor device according to the first embodiment, omitting therefore description thereof. FIG. 20 is a sectional view of a workpiece obtained by the wire bonding process step, and FIG. 21 is a sectional view of a workpiece obtained by the resin molding process step.

(12) Process Step for Forming Bumps on the Respective Draw-Out Electrodes:

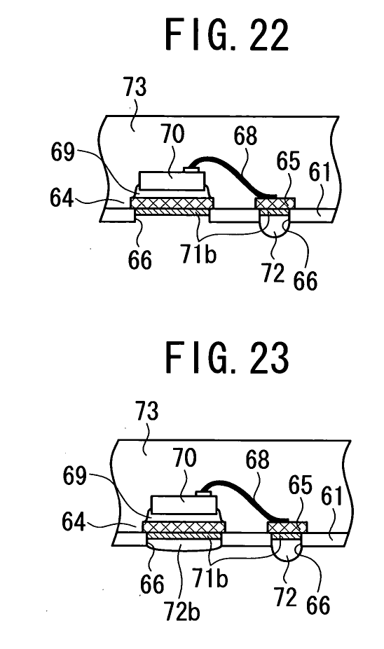

In the present process step, the bump 72 (FIG. 22) made out of a solder ball is formed on a nickel-gold film 71b formed on the side of the draw-out electrodes 65, adjacent to respective openings 66. As the material of the bump 72, a solder containing Pb may be used, however, with the present embodiment, use is made of, for example, a Pb-free solder with composition of Sn-3% Cu-0.5% Ag.

The bumps 72 are formed by causing solder balls to be adsorbed to a jig in a vacuum, disposing the solder balls at predetermined positions corresponding to the draw-out electrodes 65, respectively, and subsequently, carrying out reflow on conditions of 260° C., and 10 minutes.

FIG. 22 is a sectional view of a workpiece obtained by the present process step.

(13) Dicing Process Step:

Since the process steps as described above are applied to an aggregate having a plurality of ones shown in FIG. 14, each one as a unit, the aggregation is diced into individual units, as shown in FIG. 14.

The semiconductor device according to the invention can be obtained by applying those process steps as described above.

With the third embodiment of the invention, there has been described in detail a case of forming the openings 67 by use of the carbon dioxide gas laser by way of example, however, the openings 67 may be formed by other methods. For example, the openings 67 may be preformed at desired positions of the insulting film 61 by use of a press using a metal mold, and subsequently, the copper foil may be laminated to the insulting film 61 as shown in FIG. 15B, thereby forming the copper-laminated sheet 60. However, with the adoption of this method as it is, because an etchant makes ingress from the respective openings 67 during the etching process step (5), thereby preventing the binding electrode, and the draw-out electrodes from being formed, a dry film resist (not shown) is laminated to the insulting film 61 from the back surface thereof, or a resist in liquid state is applied thereto and kept dried. The resist on the back surface is removed during the stripping process step (6), whereupon the workpiece will be in a shape shown in FIG. 18.

A fourth embodiment of the invention may have a configuration, as shown in FIG. 23, such that a solder layer 72b is formed on a nickel-gold film 71b on the back surface of the binding electrode in FIG. 14.

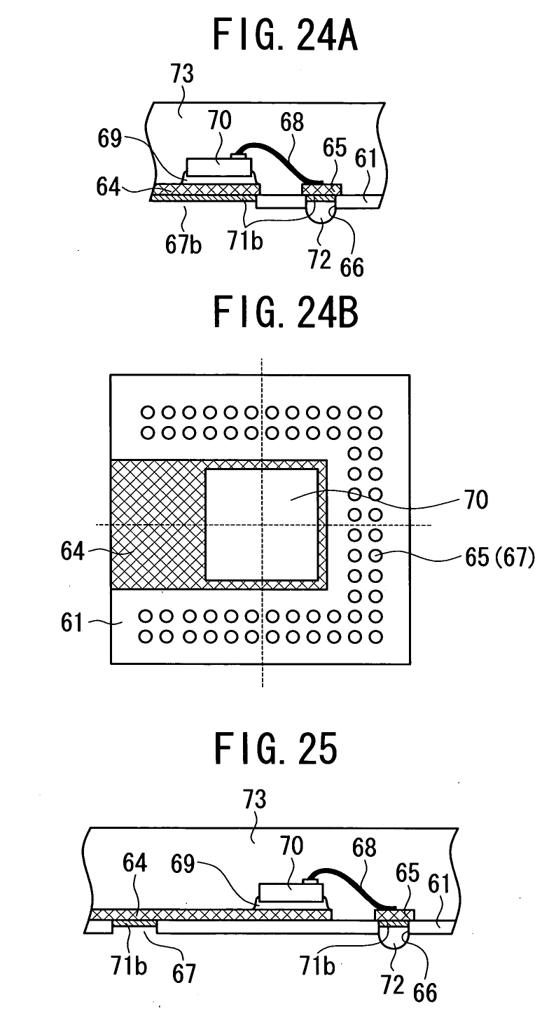

With the present embodiment of the invention, there has been described in detail a case where an opening formed in an insulting film 61, corresponding to the back surface of the binding electrode 64, is located only at a position directly under a semiconductor element 70, however, with a fifth embodiment of the invention, a binding electrode 64 doubling as a heat radiation sheet is extended in order to enhance heat radiation property, and an opening 67 as well is extended so as to correspond to the binding electrode 64 as extended, thereby being enlarged as shown FIG. 24A, and FIG. 24B which is plan view. Otherwise, instead of at the position directly under the semiconductor element 70, the opening 67 may be provided at a position away from the position directly under the semiconductor element 70, facing the binding electrode 64 as extended, doubling as the heat radiation sheet, as with the case of a sixth embodiment of the invention, shown in FIG. 25.

Now, a seventh embodiment of the invention is described hereinafter with reference to the accompanying drawing.

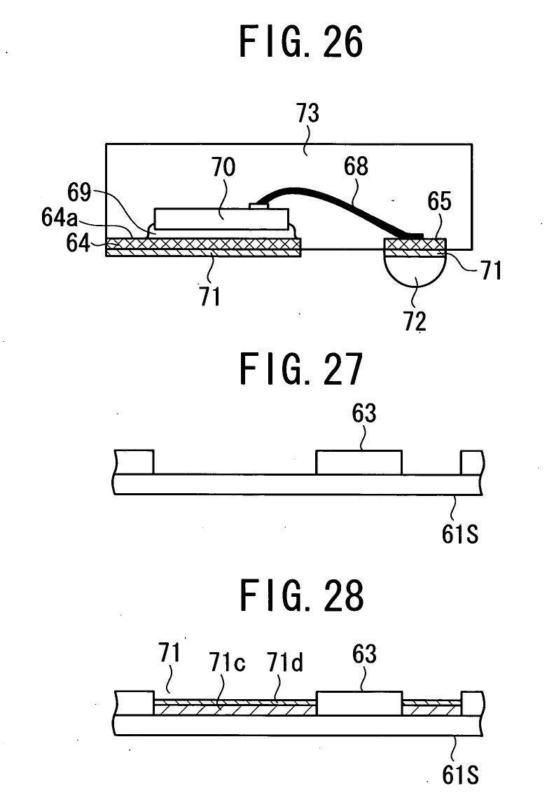

FIG. 26 is a sectional view broadly showing the seventh embodiment of a semiconductor device according to the invention.

The present semiconductor device comprises a binding electrode 64, and draw-out electrodes 65, formed on the same plane, and a semiconductor element 70 installed through the intermediary of a high melting point solder layer 69, disposed on top of the binding electrode 64, wherein electrodes provided on the upper surface of the semiconductor element 70 are bonded to the draw-out electrodes 65 by a gold wire 68, respectively. The face of the semiconductor device, on a side thereof, facing the semiconductor element, that is, the upper face thereof, shown in the figure, is entirely resin-encapsulated with a synthetic resin 73 for protection. Further, a solder bump 72 is bonded to each of the draw-out electrodes 65, and the lower end face of the binding electrode 64 is exposed to the atmosphere. In this case, the binding electrode 64 doubling as a heat radiation sheet is extended toward, for example, the left-hand side in FIG. 26, on the lower side of the semiconductor element 70, so as to have a heat radiation region 64a located outside of a region of the semiconductor element 70 in a plan view when the semiconductor element 70 is disposed over the binding electrode 64.

Next, a method of fabricating the semiconductor device according to the seventh embodiment of the invention is described by way of example with reference to the accompanying drawings. The method of fabricating the semiconductor device comprises process steps (1) to (12) as described hereinafter. That is,

(1) Process Step for Forming the Binding Electrode and the Draw-Out Electrodes by Forming a Copper Plating over a Stainless Steel Substrate:

pretreatment: A stainless steel substrate (e.g. SUS430), for example, 1 mm thick is immersed in a 5% hydrochloric acid solution at room temperature for 1 minute, and subsequently, is washed in water before being dried

(2) Process Step for Lamination of a Dry Film Resist:

Use is made of a laminator for dry film resists. The process step for lamination is executed with, for example, lamination temperature at 50° C., lamination rate at 1.5 m/min, and air cylinder pressure at 0.34 MPa. After lamination, a workpiece is held at room temperature for 15 minutes.

(3) Exposure Process Step:

For an aligner, the contact exposure type using a negative mask having a desired pattern is adopted, and an exposure quantity is set to, for example, 80 mJ/cm².

(4) Development Process Step:

The present process step is the same as the development process step of the method of fabricating the semiconductor device according to the first embodiment. FIG. 27 is a sectional view of a workpiece obtained by this process step, and a dry film resist 63 is patterned on the stainless steel substrate 61S.

(5) Plating Process Step:

(i) Copper Plating Step

As pre-treatment for copper plating, a workpiece is immersed in a 10% sulfuric acid solution at room temperature for 3 minutes, and subsequently, is washed in water. Next, electroplating is applied to the workpiece in a plating bath of a copper sulfate at current density of 2 A/dm² for 200 minutes. By so doing, a copper plating film 71c 70 μm thick is formed in a groove surrounded by the dry film resist 63.

(ii) Formation of a Nickel-Gold Plating Film (Part 1): Electroplating Process Step

A plating film 71d comprised of a nickel film 4 μm thick and a gold film 0.5 μm thick is subsequently formed on the copper plating film 71c. The method of forming the same is electroplating. Activation processing is applied to the workpiece, and is post-dipped in dilute hydrochloric acid.

Subsequently, nickel plating is applied to the workpiece in a watts nickel bath on conditions of temperature at 50° C., and current density at 2 A/dm², whereupon a nickel plating film about 4 μm thick is formed. Thereafter, total strike plating is applied thereto at current density of 1 A/dm², for 30 minutes, and subsequently, gold plating is applied thereto in a cyanide bath on conditions of temperature at 60° C., and current density at 0.5 A/dm² for 1 minute 30 seconds, whereupon a gold plating film 0.5 μm thick is formed.

FIG. 28 shows a workpiece obtained by the present plating process step, and a nickel-gold film 71 is formed therein.

(6) Stripping Process Step:

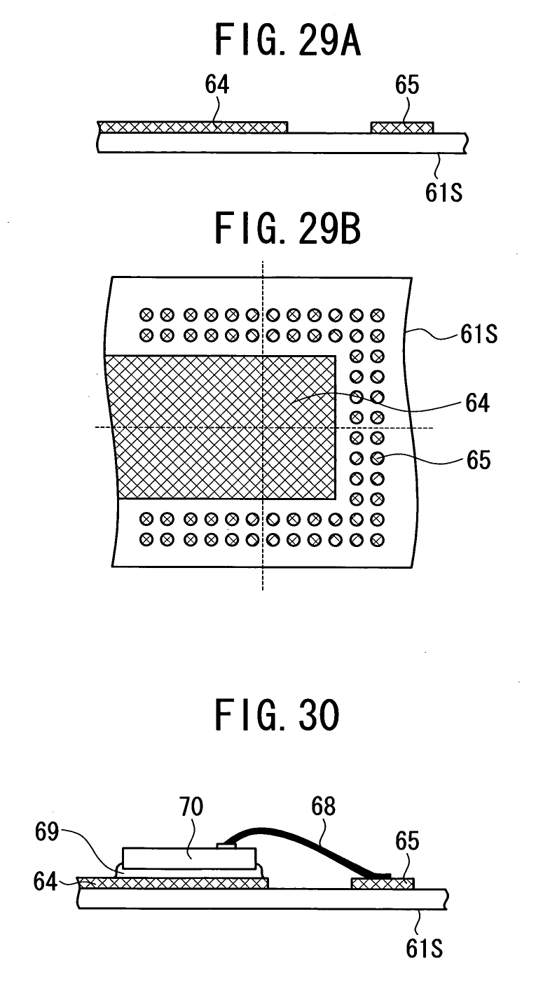

Use is made of a remover of demethyl sulfoxide base amine, and the workpiece obtained by the above-described process steps is immersed in the remover kept at 60° C. for 30 minutes, thereby stripping the dry film resist 63 off, whereupon there is formed a desired pattern of the binding electrode 64 and the draw-out electrodes 65, formed on the stainless steel substrate 61S. FIGS. 29A and 29B show the workpiece obtained by the present process step, and FIG. 29A is a sectional view thereof while FIG. 29B is a plan view thereof by way of example.

In this case, the binding electrode 64 is extended toward the left-hand side in FIGS. 29A and 29B such that a region is formed outside of the region of the semiconductor element in a plan view when the semiconductor element is disposed over the binding electrode 64.

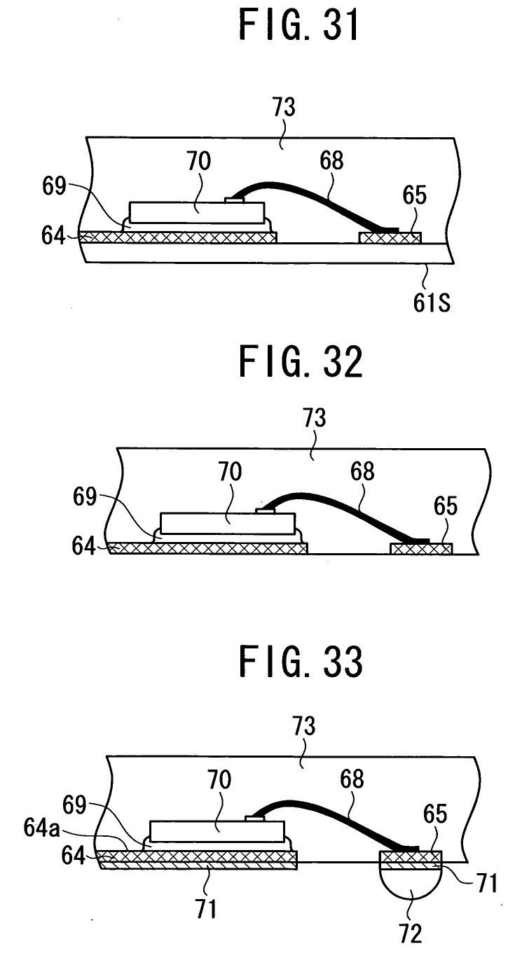

A die bonding process step (7) subsequent to the stripping process step, a wire bonding process step (8), and a resin molding process step (9) are the same as those corresponding thereto, respectively, of the method of fabricating the semiconductor device according to the first embodiment. FIG. 30 is a sectional view showing a workpiece obtained by the wire bonding process step, and FIG. 31 is a sectional view showing a workpiece obtained by the resin molding process step.

(10) Process Step for Stripping from a Support Substrate:

The stainless steel substrate 61S is stripped from the interfaces thereof, with the molding resin 73, and the electrodes 64, 65, respectively. The stainless steel substrate 61S can be mechanically stripped from these interfaces with ease. FIG. 32 is a sectional view of a workpiece obtained by the present process step.

(11) Formation of a Nickel-Gold Plating Film (part 2): Eletroless Plating Process Step

In the present process step, a plating film 71 comprised of a nickel film 4 μm thick, and a gold film 0.5 μm thick is formed. For a method of forming the plating film, use is made of the electroless plating method as previously described. The method of forming the plating film in this case is the same as that adopted for the method of fabricating the semiconductor device according to the first embodiment.

(12) Process Step for Forming Bumps on the Respective Draw-Out Electrodes:

A bump 72 made out of a solder ball is formed on the plating film 71 provided on the underside of the respective draw-out electrodes 65. As the material of the bump 72, a solder containing Pb may be used, however, with the present embodiment, use is made of a Pb-free solder with composition of Sn-3% Cu-0.5% Ag.

The bumps 72 are formed in the same manner as previously described in “process step of forming bumps on the respective draw-out electrodes” for the method of fabricating the semiconductor device according to the third embodiment. FIG. 33 is a sectional view showing a workpiece obtained by the present process step.

(13) Dicing Process Step:

Since the process steps as described above are applied to an aggregate having a plurality of ones shown in FIG. 26, each one as a unit, the aggregation is diced into individual units, as shown in FIG. 26.

Now, a method of fabricating a semiconductor device according to an eighth embodiment of the invention is described hereinafter.

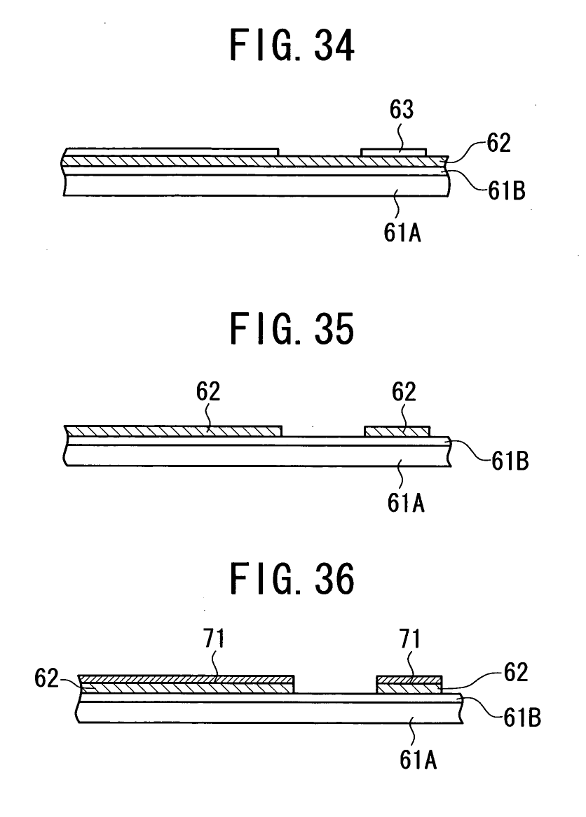

FIG. 34 is a sectional view broadly showing the semiconductor device according to the eighth embodiment of the invention.

(1) Formation of a Binding Electrode, and Draw-Out Electrodes by Laminating a Copper Foil onto a Glass Epoxy Substrate with a Silicon Resin Film Formed Thereon: Process Step for Lamination of a Copper Foil

A glass epoxy substrate 61A with a silicon resin 61B film, serving as a mold-releasing adhesive, preformed thereon, is prepared. At the interface between the glass epoxy substrate 61A and the silicon resin 61B film, silicon resin 61B is diffused into glass fiber, thereby keeping the glass epoxy substrate 61A in intimate contact with the silicon resin 61B film. A so-called copper-laminated sheet is formed by laminating a copper foil 62, for example, 75 μm thick, onto the silicon resin 61B film. A lamination method is carried out by, for example, pressing the copper foil 62 at 200° C.

(2) Pre-Treatment Process Step:

With the use of a conveyer-type apparatus, the copper-laminated sheet is immersed in a chemical polishing liquid composed of sulfuric acid and aqueous hydrogen peroxide, and the surface of the copper foil 62 is cleaned by applying chemical polishing thereto to be followed by washing in water and drying.

(3) Process Step for Lamination of a Dry Film Resist, Exposure Process Step, and Development Process Step:

These process steps are the same as those corresponding thereto, respectively, for the method of fabricating the semiconductor device according to the seventh embodiment of the invention except for use of a dry film resist 63, for example, 10 μm thick. After the development process step, the dry film resist 85 is patterned on the copper foil 84. FIG. 34 is a sectional view showing a workpiece obtained by those process steps.

(4) Etching Process Step and Stripping Process Step:

For etching of the copper foil 62, a spray-type conveyer system is used, and etching is carried out at 40° C., using an etchant composed of a mixed liquid of hydrochloric acid and iron (III) chloride. After the etching, the workpiece is washed in a 3% hydrochloric acid solution, and subsequently, is washed in water. Stripping of the dry film resist 63 is carried out in a spray-type conveyer system along the same line, linked with an etching system, using a remover containing 2% sodium hydroxide at 40° C., whereupon the copper foil 62 in a desired pattern is formed. FIG. 35 is a sectional view of a workpiece obtained by these process steps. The plan view of the workpiece is the same as that shown in FIG. 29B.

(5) Process Step for Formation of a Nickel-Gold Plating Film (Part 1): Eletroless Plating Process Step

A plating film 71 comprised of a nickel film 4 μm thick, and a gold film 0.5 μm thick is formed on the copper foil 62. A method of forming the plating film is the electroless plating method. First, degreasing of the workpiece is carried out to be followed by soft etching in sodium peroxosulfate. Subsequently, smut is removed in dilute sulfuric acid, and the workpiece is pre-dipped in dilute hydrochloric acid after washing the same in water. Thereafter, activation processing is applied to the workpiece, which is then post-dipped in dilute hydrochloric acid, and further, eletroless nickel plating at 80° C. is applied thereto for 30 minutes. By so doing, the nickel plating film about 4 μm thick is formed.

After washing the workpiece in water, activation processing in dilute sulfuric acid is applied thereto, and displacement gold plating is applied thereto. After the workpiece is washed in water, gold plating is applied thereto in a gold neutral plating bath at 60° C. for 30 minutes, thereby forming a gold plating film 0.5 μm thick. Subsequently, the workpiece is washed in water, and dried.

The nickel-gold film 71 is formed by the process step described. FIG. 36 is a sectional view of a workpiece obtained by the present process step.

(6) Die Bonding Process Step, Wire Bonding Process Step, and Resin Molding Process Step:

These process steps from a wire bonding process step through a resin molding process step are the same as those corresponding thereto, respectively, for the method of fabricating the semiconductor device according to the seventh embodiment of the invention.

(7) Process Step for Stripping from a Support Substrate:

By stripping the glass epoxy substrate 61A with the silicon resin 61B film formed thereon from the respective interfaces thereof, with the silicon resin 61B film, the binding electrode 64, the draw-out electrodes 65, and the molding resin 73, the semiconductor device according to the invention as shown in FIG. 31 is completed.

Since the silicon resin 61B film is formed on the glass epoxy substrate 61A, the glass epoxy substrate 61A can be mechanically stripped with ease from the interface thereof, with the silicon resin 61B film.

(8) Process Step for Formation of a Nickel-Gold Plating Film (Part 2): Eletroless Plating Process Step and Process Step of Forming a Bump on the Respective Draw-Out Electrodes.

A dicing process step is the same as that in the case of the seventh embodiment of the invention.

The above-described methods of fabricating the semiconductor device can be applied even if capacitors, resistances, and so forth are included in the workpiece, and needless to say, can be applied even if the workpiece is exposed not only to the atmosphere, but also in a vacuum.

It is needles to say that solder may be formed on the nickel-gold film 71 which is exposed to the atmosphere at the side of the binding electrode doubling as the heat radiation sheet.

A ninth embodiment of a semiconductor device according to the invention is described hereinafter with reference to the accompanying drawings.

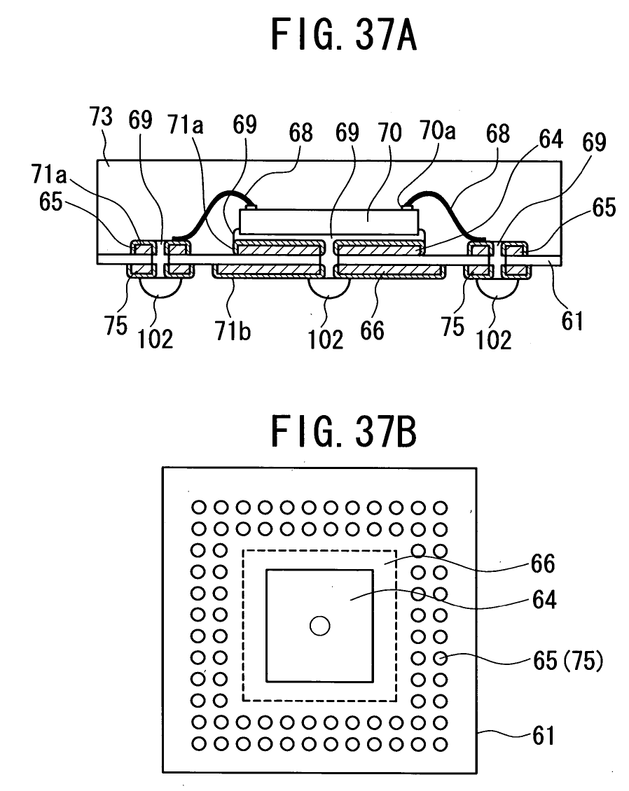

FIGS. 37A and 37B are views, showing the semiconductor device according to the ninth embodiment of invention, in which FIG. 37A is a sectional view of the semiconductor device, and FIG. 37B is a plan view thereof.

As shown in FIG. 37A, a binding electrode 64 formed by etching a copper foil laminated to an insulting film 61, having a through-hole at the center thereof, and a multitude of draw-out electrodes 65, each having a through-hole at the center thereof, disposed in such a way as to, surround the binding electrode 64 are provided on one side face of the insulting film 61 while a heat radiation sheet 66 formed by etching a copper foil laminated to the insulting film 61, having a through-hole at the center thereof, and connection electrodes 75, each having a through-hole at the center thereof, are provided on the other side face of the insulting film 61. As shown in FIG. 37B, the connection electrodes 75 are disposed in such a way as to surround the heat radiation sheet 66, and each of the connection electrodes 75 has the through-hole at the center thereof.

The respective draw-out electrodes 65 and the respective connection electrodes 75 as well as the binding electrode 64 and the heat radiation sheet 66 are disposed so as to oppose each other with the insulting film 61 interposed therebetween, and small holes formed in respective elements, opposite to each other, are aligned with each other, thereby forming respective integrated through-holes in which the small holes communicate with each other. A plating layer amenable to soldering and gold wire bonding, for example, a nickel-gold film 71a is formed on the draw-out electrodes 65, the connection electrodes 75, the binding electrode 64 and the heat radiation sheet 66, respectively, while the respective integrated through-holes are filled up with a high melting point solder 69 having high bond strength and excellent thermal conductivity.

A semiconductor element 70 is integrally laminated to the binding electrode 64 made out of the copper foil with both the high melting point solder 69 serving as an electrically conductive layer, and the nickel-gold film 71 a interposed therebetween, and further, the binding electrode 64 made out of the copper foil is laminated to the heat radiation sheet 66 made out of the copper foil with the insulting film 61 interposed therebetween.

Electrodes 70a on top of the semiconductor element 70 and the draw-out electrodes 65 are interconnected via a gold wire 68, respectively, and all elements over the insulting film 61 are encapsulated with an epoxy resin 73.

On the other hand, the present embodiment has a configuration such that the heat radiation sheet 66, and the connection electrodes 75, disposed on a side of the insulting film 61, opposite from the binding electrode 64, are exposed to outside, blocking the integrated through-holes with a solder bump 102, respectively.

Because of the above-described configuration of the semiconductor device according to the present embodiment, it is possible to simultaneously form the binding electrode 64, the heat radiation sheet 66, the draw-out electrodes 65, and the connection electrodes 75 by, for example, laminating the copper foils to both the side faces of the insulting film 61, respectively, to thereby form a support substrate with the integrated through-holes formed by a drill or a press, to be followed by etching. Furthermore, strong coupling between the binding electrode 64, and the heat radiation sheet 66 as well as between the draw-out electrodes 65, and the connection electrodes 75 can be implemented with an electrically conductive material filling up the respective integrated through-holes.

With the configuration as described, since the binding electrode 64 is strongly coupled to the heat radiation sheet 66 with the high melting point solder 69 filling up the respective integrated through-holes, high connection strength can be secured, and there is no likelihood that the binding electrode 64, the draw-out electrodes 65, and the insulation resin 73 for encapsulation are stripped from the insulting film 61, and further, the heat radiation sheet 66, and the connection electrodes 75, disposed on the side of the insulting film 61, opposite from the binding electrode 64, and so forth, are stripped from the insulting film 61, so that the semiconductor device low in profile, having large adhesion force can be obtained. At the same time, heat generated in the semiconductor element 70 is conducted to the binding electrode 64 through the intermediary of the high melting point solder 69, and is further conducted to the heat radiation sheet 66 through the intermediary of the high melting point solder 69, so that efficient radiation of heat can be effected.

Further, heat conducted from the semiconductor element 70 to the draw-out electrodes 65 via the gold wire 68, respectively, is conducted to the connection electrodes 75 via the high melting point solder 69 to be thereby radiated.

For the insulting film 61, an aramid non-woven fabric epoxy film is preferably adopted. The film is obtained by causing an epoxy resin, which is a thermosetting resin, to permeate a heat resistant aramid non-woven fabric, and as such, remains stable in shape during process steps affected by heat, so that it has an advantage of precluding the risk of electrode positions being misaligned.

Further, the solder bump 102 is for connecting those electrodes 64, 65 with circuits of a circuit board, respectively, when mounting the semiconductor device on the circuit board, and is made of a Pb-free solder composed of, for example, Sn, Ag, and Cu. Incidentally with the respective embodiments described, the solder bump 102 is shown in the figures as being hemispherical in side view, however, the solder bump 102 under the heat radiation sheet 66 need not necessarily be hemispherical, but may be substantially in the shape of, for example, a laterally extended trapezoid.

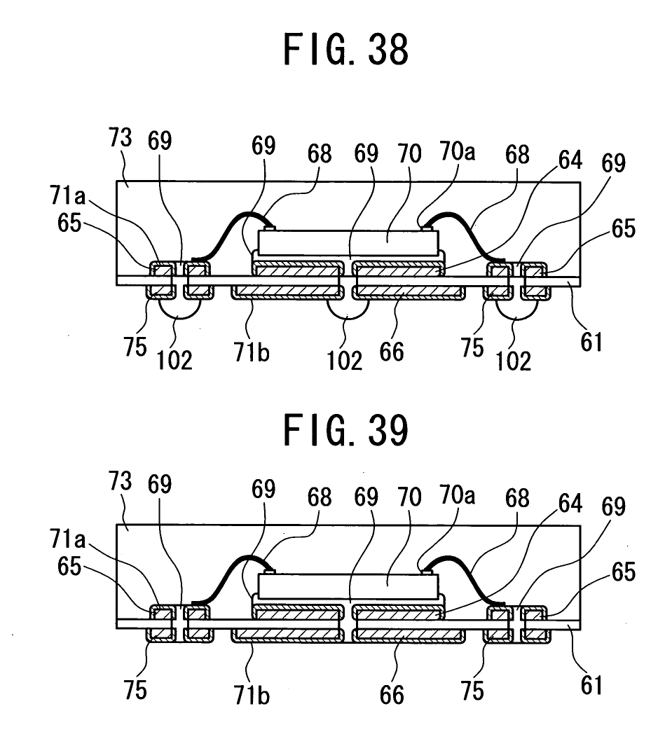

Next, a tenth embodiment of a semiconductor device according to the invention is described hereinafter with reference to FIG. 38.

With the semiconductor device according to the present embodiment as well as the semiconductor device according to the ninth embodiment, a semiconductor element 70 is integrally laminated to a binding electrode 64 made out of a copper foil with both a high melting point solder 69 serving as an electrically conductive layer, and a nickel-gold film 71 a interposed therebetween, and further, the binding electrode 64 made out of the copper foil is laminated to the heat radiation sheet 66 made out of a copper foil with an insulting film 61 interposed therebetween. Further, the former is the same as the latter in that small holes provided in the binding electrode 64, the insulting film 61, and the heat radiation sheet 66, respectively, are concentrically disposed to thereby secure a through-hole, and small holes provided in the respective draw-out electrodes 65, the insulting film 61, and the respective connection electrodes 75, respectively, are aligned with each other to thereby secure respective through-holes.

The semiconductor device according to the present embodiment differs from the semiconductor device according to the ninth embodiment in that the interiors of the respective through-holes, partway from the side of the binding electrode 64, and the respective draw-out electrodes 65, respectively, are filled up with a high melting point solder 69 while the remainders of the interiors of the respective through-holes, that is, the interiors partway from the side of the heat radiation sheet 66, and the respective connection electrodes 75, respectively, are filled up with the solder for forming the solder bump 102.

With such a configuration as described, since welding is implemented by filling the respective through-holes up with the high melting point solder 69, and the solder for the solder bump 102, applied from respective sides of each of the through-holes, not only connection strength is secured, but also excellent conduction of heat can be effected. Accordingly, heat generated in the semiconductor element 70 is conducted to the binding electrode 64 through the intermediary of the high melting point solder 69, and is further conducted to the solder for the solder bump 102, and the heat radiation sheet 66 through the intermediary of the high melting point solder 69 in the respective through-holes, thereby effecting radiation of heat with high efficiency.

Furthermore, heat generated in the semiconductor element 70, and conducted to the respective draw-out electrodes 65 via a gold wire 68, respectively, as well is conducted to the respective solder bumps 102, and the respective connection electrodes 75 through the intermediary of the high melting point solder 69 in the respective through-holes, thereby effecting radiation of heat.

In this case, it is to be pointed out that respective constituents of the high melting point solder 69 and the solder for the solder bump 102, are mutually diffused into each other at an interface therebetween, thereby forming an alloy phase, respectively, so that the interface is evidently not so distinct as shown in the figure.

Now, an eleventh embodiment of a semiconductor device according to the invention is described hereinafter with reference to FIG. 39.

With the semiconductor device according to the present embodiment as well as the semiconductor device according to the ninth embodiment, a semiconductor element 70 is integrally laminated to a binding electrode 64 made out of a copper foil with both a high melting point solder 69, and a nickel-gold film 71 is interposed therebetween, and further, the binding electrode 64 made out of the copper foil is laminated to the heat radiation sheet 66 made out of a copper foil with an insulting film 61 interposed therebetween. Further, the former is the same as the latter in that small holes provided in the binding electrode 64, the insulting film 61, and the heat radiation sheet 66, respectively, as well as small holes provided in the respective draw-out electrodes 65, the insulting film 61, and the respective connection electrodes 75, respectively, are concentrically disposed to thereby secure respective through-holes.

The former differs from the latter only in that the respective through-holes are filled up with the high melting point solder 69, and the solder bumps 102 as shown in FIG. 38 are not provided.

With such a configuration as described, since welding between the binding electrode 64, and the heat radiation sheet 66 as well as welding between the respective draw-out electrodes 65, and the respective connection electrodes 75 is implemented by filling the respective through-holes up to close to the exposure side of respective elements with the high melting point solder 69, not only connection strength is secured, but also excellent conduction of heat can be effected.

Heat generated in a semiconductor element 70 is conducted to the binding electrode 64 through the intermediary of the high melting point solder 69, and is further conducted to the heat radiation sheet 66 through the intermediary of the high melting point solder 69 in the respective through-holes, thereby effecting radiation of heat with high efficiency. Further, heat generated in the semiconductor element 70, and conducted to the respective draw-out electrodes 65 via a gold wire 68, respectively, as well is conducted to the respective connection electrodes 75 through the intermediary of the high melting point solder 69 in the respective through-holes, thereby effecting radiation of heat.

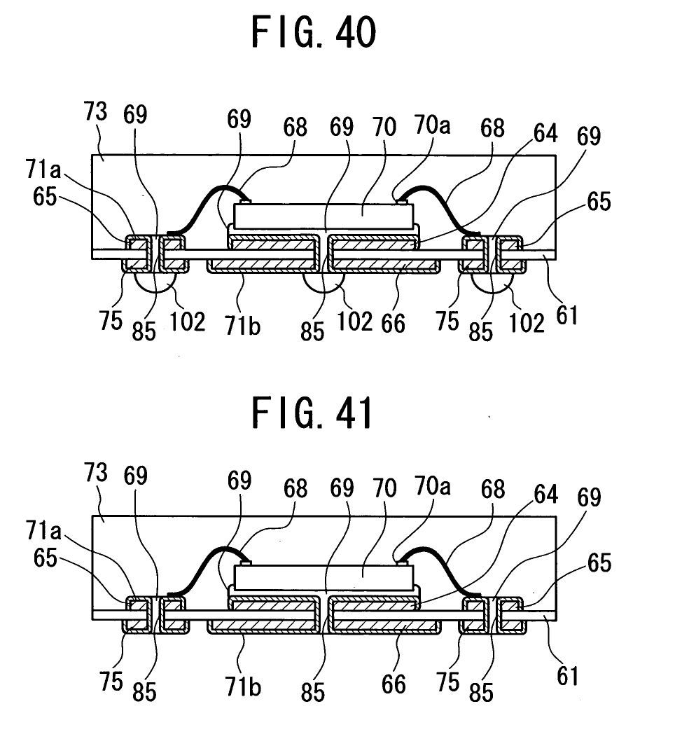

Next, a twelfth embodiment of a semiconductor device according to the invention is described hereinafter with reference to FIG. 40.

With the present semiconductor device, a binding electrode 64 formed by etching a copper foil laminated to an insulting film 61, having a through-hole at the center thereof, and a multitude of draw-out electrodes 65, each having a through-hole at the center thereof, disposed in such a way as to surround the binding electrode 64 are provided on one side face of the insulting film 61 while a heat radiation sheet 66 formed by etching a copper foil laminated to the insulting film 61, having a through-hole at the center thereof, and a multitude of connection electrodes 75, each having a through-hole at the center thereof, are provided on the other side face of the insulting film 61.

That is, small holes formed in the binding electrode 64 and the heat radiation sheet 66, respectively, and small holes formed in the respective draw-out electrodes 65 and the respective connection electrodes 75, respectively, are disposed so as to oppose each other concentrically, thereby forming respective integrated through-holes, and on the inner faces of the respective integrated through-holes, there is provided a through-hole copper plating film 85 formed at the same time when laminating the copper foil for forming the binding electrode 64, the heat radiation sheet 66, the respective draw-out electrodes 65, and the respective connection electrodes 75.

A plating layer amenable to soldering and gold wire bonding, for example, a nickel-gold film 71 a is formed on the binding electrode 64, the heat radiation sheet 66, the respective draw-out electrodes 65, the respective connection electrodes 75, and the respective through-hole copper plating films 85, and further, the respective integrated through-holes are filled up with a high melting point solder 69.

A semiconductor element 70 is installed over the nickel-gold film 71 of the binding electrode 64 with the high melting point solder 69 interposed therebetween, electrodes 70a of the semiconductor element 70 and the draw-out electrodes 65 are interconnected via a gold wire 68, respectively, and all elements over the insulting film 61 are encapsulated with an epoxy resin 73. On the other hand, the heat radiation sheet 66, and the respective connection electrodes 75 are exposed to outside, and the respective integrated through-holes, on the exposure side thereof, are blocked with a solder bump 102.

At the time of fabrication of the semiconductor device, by laminating the copper foil to both the side faces of the insulting film 61, and forming through-holes by use of a drill or a press, followed by etching, the binding electrode 64, the heat radiation sheet 66, the draw-out electrodes 65, and the connection electrodes 75 are formed at a time, and subsequently, the respective through-hole copper plating film 85 can be formed.

With such a configuration as described, since strongly coupling between the binding electrode 64 and the heat radiation sheet 66 as well as between the draw-out electrodes 65, and the connection electrodes 75 can be implemented by virtue of the respective through-hole copper plating film 85 and the high melting point solder 69, heat radiation can be effected with high efficiency.

Heat generated in the semiconductor element 70 is conducted to the binding electrode 64 through the intermediary of the high melting point solder 69, and is further conducted to the heat radiation sheet 66 through the intermediary of the respective through-hole copper plating film 85 and the high melting point solder 69, formed in the respective through-holes, thereby effecting radiation of heat with high efficiency. Furthermore, heat generated in the semiconductor element 70, and conducted to the respective draw-out electrodes 65 via a gold wire 68, respectively, as well is conducted to the respective connection electrodes 75 through the intermediary of the respective through-hole copper plating film 85, and the high melting point solder 69, in the respective through-holes, thereby effecting radiation of heat with high efficiency.

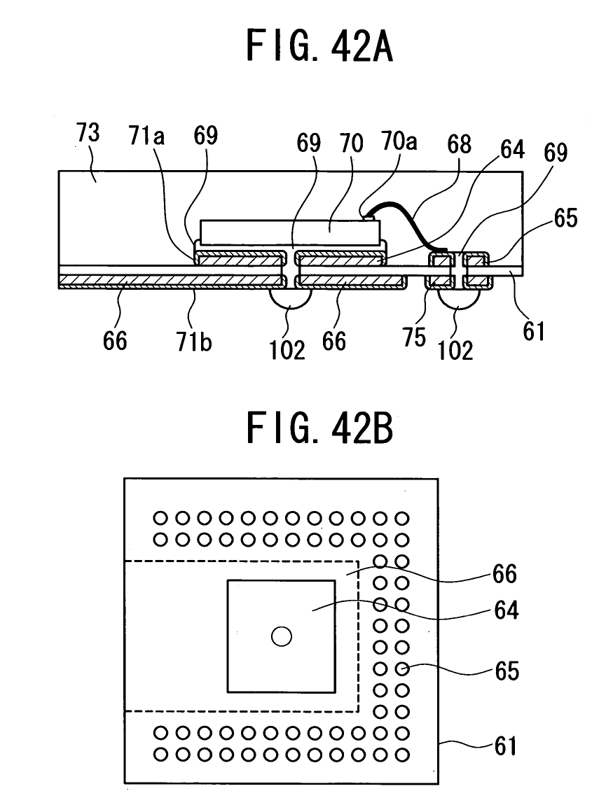

FIGS. 42A and 42B are views each showing a fourteenth embodiment of a semiconductor device according to the invention, in which FIG. 42A is a sectional view of the semiconductor device, and FIG. 42B is a plan view thereof.

With the present semiconductor device, a region of an insulting film 61, on one side thereof (in the figure, toward the left-hand side thereof), is not provided with draw-out electrodes 65, thereby being left vacant, and a heat radiation sheet 66 is provided on the entire back surface of a portion of the insulting film 61, on a side thereof, opposite from the region.

Because the heat radiation sheet 66 according to the present embodiment has an area larger than that for the respective embodiments described as above, the function of the heat radiation sheet 66 as a heat sink is enhanced while an area of the heat radiation sheet 66, in contact with a printed board, increases, so that heat radiation property thereof is further enhanced.

A ninth embodiment of a method of fabricating a semiconductor device according to the invention is described hereinafter. The method of fabricating the semiconductor device according to the embodiment comprises the following process steps.

(1) Process Step for Fabrication of a Copper-Laminated Sheet:

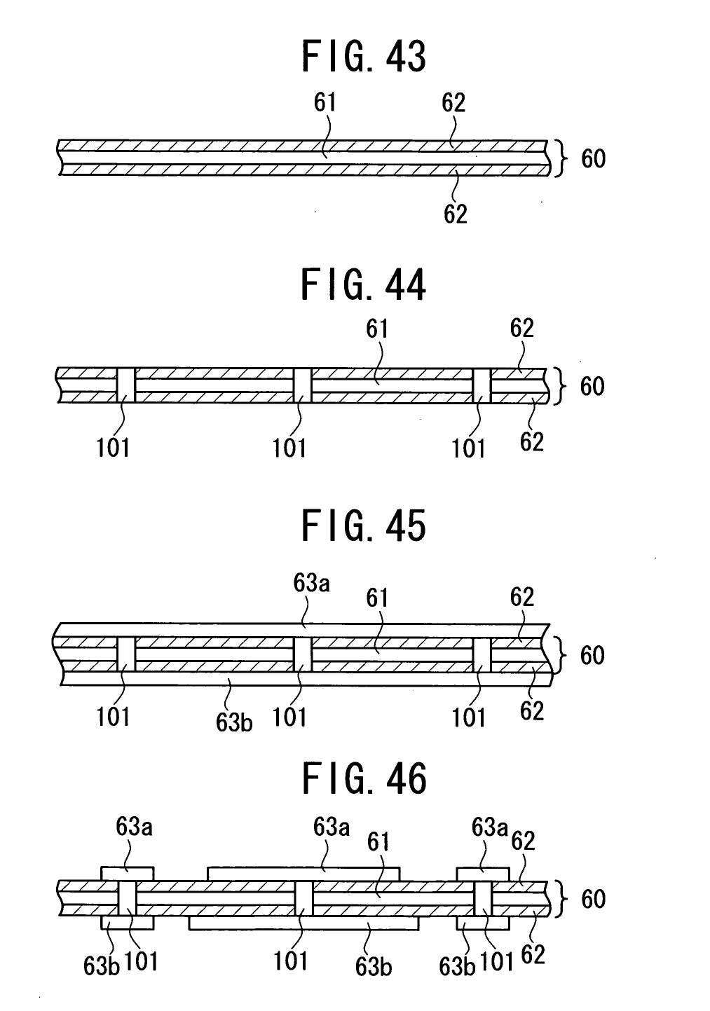

FIG. 43 is a sectional view showing a construction of a copper-laminated sheet for use in carrying out the invention. The present process step is the same as that for the method of fabricating the semiconductor device according to the first embodiment.

(2) Boring Process Step:

As shown in FIG. 44, through-holes 101 are opened at predetermined positions of a copper-laminated sheet 60, respectively, by use of a drill. The bore of each of the through-holes 101 is set to 0.3 mm. The through-holes 101 may be formed by punching the copper-laminated sheet 60 with a press using a blanking die.

(3) De-Smear Process Step:

The present process is for cleaning the respective through-holes 101 formed by the boring process step. An epoxy resin constituent of the aramid non-woven fabric epoxy film is mainly cleaned. In order to cause the epoxy resin constituent to undergo swelling, the copper-laminated sheet 60 is immersed in a conditioner liquid at 35° C. for 3 minutes to be subsequently washed in water. Thereafter, in order to cause the epoxy resin constituent to be subjected to wet etching, the copper-laminated sheet 60 is immersed in a mainly permanganic acid containing solution at 75° C. for 7 minutes to be subsequently washed in water. Then, in order to remove and clean permanganic acid, and reaction byproducts, remaining in the respective through-holes 101, the copper-laminated sheet 60 is immersed in a solution, composed of reduction processing liquid, sulfuric acid, and pure water, at 45° C. for 5 minutes to be subsequently washed in water. Subsequently, the copper-laminated sheet 60 is dried at 80° C. for 15 minutes.

(4) Process Step for Lamination of Dry Film Resists:

As shown in FIG. 45, dry film resists 63a, 63b are laminated to the copper-laminated sheet 60 as prepared from the top side and underside side thereof, respectively, with the use of a lamination apparatus. The present process step, an exposure process step (5), a development process step (6), an etching process step (7), and a stripping process step (8) are the same as those corresponding thereto, respectively, of the method of fabricating the semiconductor device according to the first embodiment.

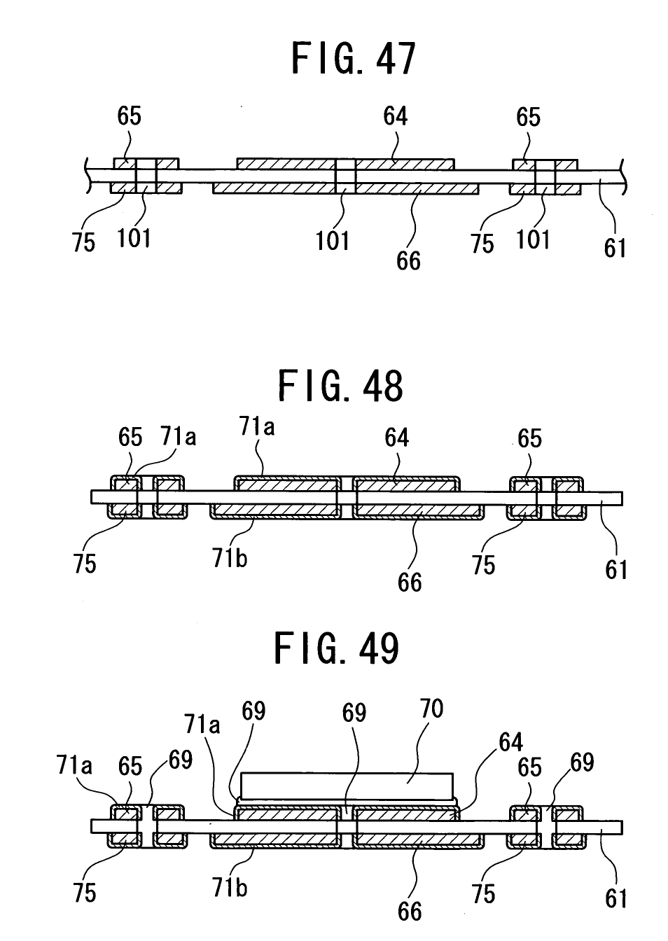

FIG. 46 is a sectional view of a workpiece in a state where the development process step has been completed. As shown in the figure, the dry film resists 63a, 63b, having desired patterns, respectively, are formed on copper foils 62, 62, respectively. Further, FIG. 47 is a sectional view of a workpiece after stripping as described above.

(9) Plating Process Step:

In the present process step, a plating film comprised of, for example, a nickel film 4 μm thick, and a gold film 0.5 μm thick is formed on the respective surfaces of a binding electrode 64, respective draw-out electrodes 65, a heat radiation sheet 66, and respective connection electrodes 75, formed by etching the copper foils 62 provided on both sides of an insulting film 61, respectively. The plating process step itself is the same as has already been described.

FIG. 48 is a sectional view of a workpiece after the plating process step as described above. As shown in the figure, nickel-gold films 71a, 71b are formed on the surfaces of the binding electrode 64, respective draw-out electrodes 65, heat radiation sheet 66, and respective connection electrodes 75, respectively, on respective sides of the insulting film 61.

(10) Process Step for Die Bonding and Blocking Through-Holes in the Respective Draw-Out Electrodes:

In the present process step, while die bonding of a semiconductor element 70 is implemented with a high melting point solder 69, through-holes in the respective draw-out electrodes 65 are filled up with the high melting point solder 69. In this case, use is made of a high melting point solder of an Sn—Pb base (for example, 10% Sn, and 90% Pb), which is heated to a temperature not lower than the melting point thereof (for example, 300° C.), and a proper amount of the high melting point solder is disposed on the binding electrode 64, and the respective draw-out electrodes 65, thereby mounting the semiconductor element 70 over the binding electrode 64, whereupon the binding electrode 64 is bonded to the semiconductor element 70 through the intermediary of the high melting point solder 69, and further, the high melting point solder 69 enters a through-hole in the binding electrode 64 to fill the same up, thereby connecting the binding electrode 64 with the heat radiation sheet 66. Further, the high melting point solder 69 enters the respective through-holes in the draw-out electrodes 65, thereby connecting the respective through-holes in the draw-out electrodes 65 with the respective connection electrodes 75.

FIG. 49 is a sectional view of a workpiece after completion of the process step for die bonding, and blocking through-holes in the respective draw-out electrodes.

(11) Wire Bonding Process Step:

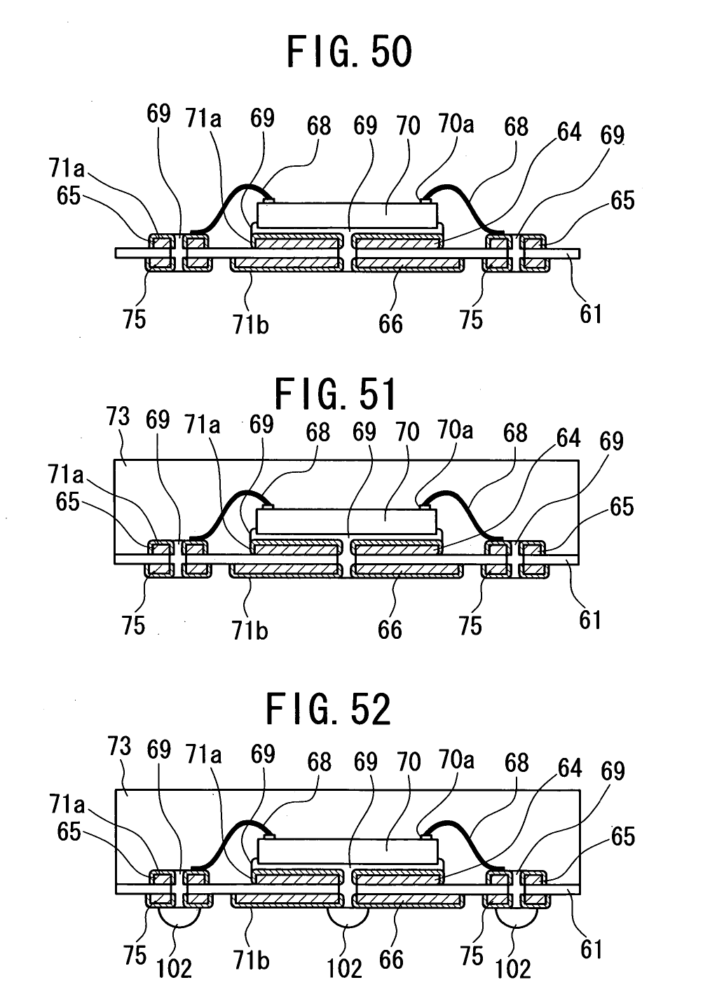

The present process is the same as has already been described. FIG. 50 is a sectional view of a workpiece after completion of the wire bonding process step.

(12) Resin Molding Process Step:

In the present process step, a circuit-forming surface in whole is encapsulated with resin. More specifically, as shown in FIG. 51, the circuit-forming surface in whole is encapsulated with an insulating resin 73 by a printing method or a transfer molding method. Although the present process step as well is the same as that for the method of fabricating the semiconductor device according to the first embodiment, the through holes are blocked in advance, the insulating resin 73 is not leaked out.

(13) Process Step for Forming Solder Bumps:

As shown in FIG. 52, formation of solder bumps 102 connected with the high melting point solder 69 formed in the respective through-holes of the heat radiation sheet 66, and the respective connection electrodes 75 is executed. The process step for forming solder bumps itself is the same as has already been described, however, in the present reflow process, the solder melts on, and adheres to the nickel-gold film 71b on the peripheries of the respective through-holes in the heat radiation sheet 66, and the respective connection electrodes 75, thereby forming the respective solder bumps 102 in metallic bond with the high melting point solder 69, 69, inside the respective through-holes. The heat generated in the semiconductor element 70 is conducted through metal conductors to be thereby radiated to outside with ease from the heat radiation sheet 66, and the respective connection electrodes 75.

(14) Dicing Process Step:

Finally, a plurality of the semiconductor devices formed as described above, over a support substrate, are diced into individual semiconductor devices by the unit of the one shown in FIG. 37B, thereby obtaining the semiconductor device.

Now, a tenth embodiment of a method of fabricating the semiconductor device shown in FIG. 38 according to the invention is described hereinafter.

The method of fabricating the semiconductor device shown in FIG. 38 is the same as the method of fabricating the semiconductor device according to the ninth embodiment of the invention except that, in the process step for the die bonding and blocking the through-holes in the respective draw-out electrodes (10) of the ninth embodiment, an amount of the high melting point solder 69 is decreased so as to be just enough to block the through-hole of the binding electrode 64, and the respective through-holes of the draw-out electrodes 65, and in the process step for forming the solder bumps (12), the solder enters deep inside the respective through-holes, thereby forming the respective solder bumps 102 in metallic bond with the high melting point solder 69.

An eleventh embodiment of a method of fabricating the semiconductor device shown in FIG. 39, according to the invention, is described hereinafter.

The method of fabricating the semiconductor device shown in FIG. 39 is the same as the method of fabricating the semiconductor device according to the ninth embodiment of the invention except that the process step for forming the solder bumps (12) of the ninth embodiment is dispensed with.

A method of fabricating the semiconductor device according to the twelfth embodiment of the invention, shown in FIG. 40, is described hereinafter.

With the present embodiment, the binding electrode 64, and the heat radiation sheet 66 as well as the respective draw-out electrodes 65, and the respective connection electrodes 75 are interconnected by applying through-hole copper plating in advance. A “process step for formation of through-hole copper plating film” as described hereinafter is added between the previously-described de-smear process step (3) and the previously-described process step for lamination of the dry film resists (4).

Process step for formation of through-hole copper plating film:

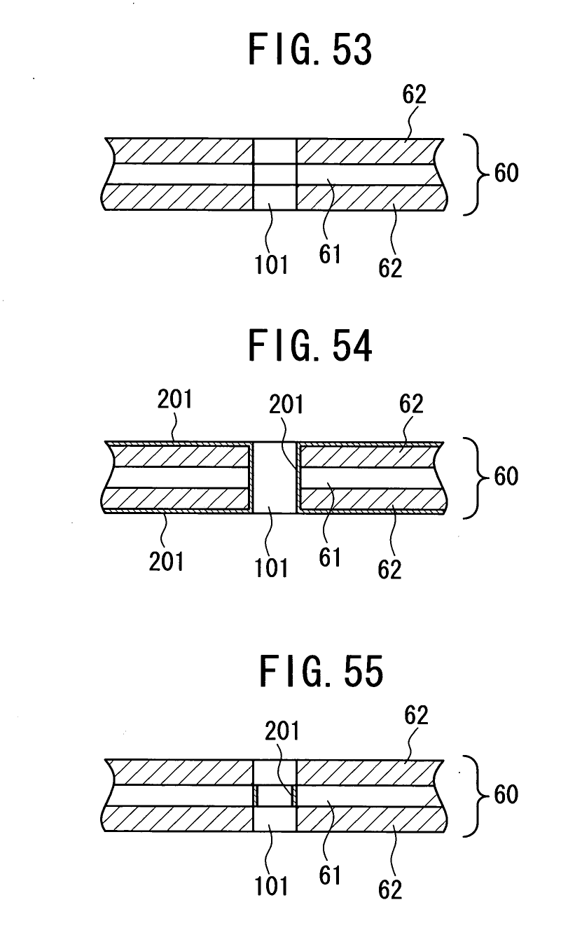

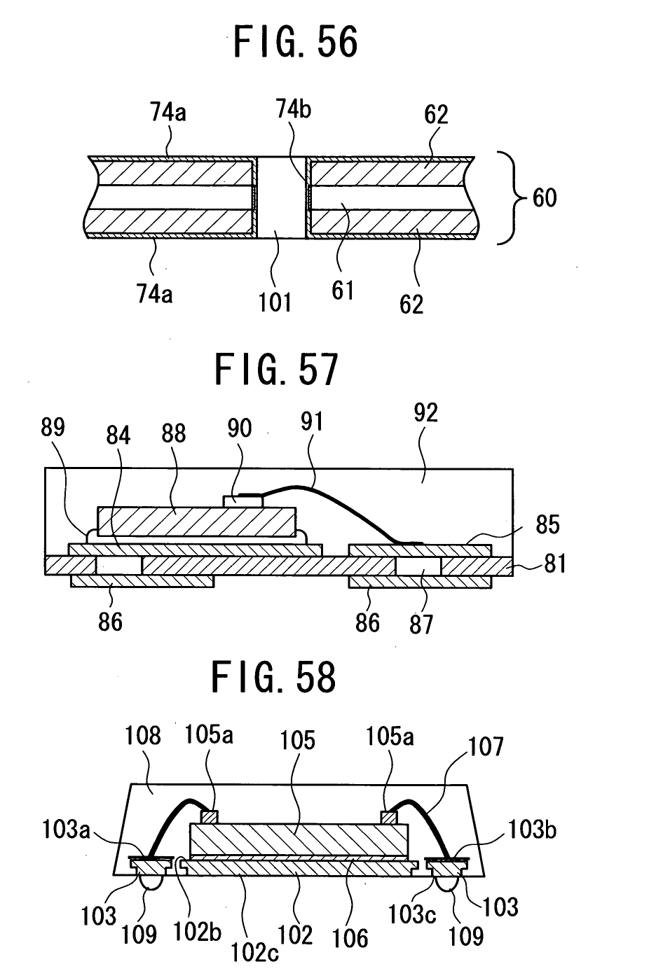

(a) A support substrate of three-layer structure, comprised of an insulting film 61 made out of the aramid non-woven fabric epoxy film, with copper foils 62, 62, laminated to the top and underside of the insulting film 61, respectively, is prepared, and, as shown in FIG. 53, the support substrate in a state prior to the last drying process step of the de-smear process step is immersed in a degreasing liquid to thereby degrease the surface thereof, to be subsequently washed in water. For the degreasing liquid, use is made of a solution containing 5% weak alkaline cleaner, at 54° C., and time for immersion in the degreasing liquid is set to 40 seconds.
(b) The support substrate is immersed in a solution containing 78% carbon treatment agent, at 34° C. for about 35 seconds, and is dried with an air knife to be subsequently washed in water.
(c) The support substrate is immersed in a solution containing 2.5% weak alkaline cleaner conditioner, kept at 25° C. for about 40 seconds to be subsequently washed in water.
(d) A step under (b) above is repeated again, whereupon carbon black 201 adsorbs on the entire surface of the support substrate, including the inner faces of the through-holes, respectively, as shown in FIG. 54.
(e) Subsequently, the carbon black 201 adsorbing on the surfaces of the copper foils is removed by etching. As an etchant in this case, use is made of an etching solution at 40° C. of pure water containing 25.0 g/L of copper sulfate penta-hydrate, 8,5 vol. % of 98% sulfuric acid, 3 vol. % of an etchant of hydrate type sulfuric acid, and 4.5 vol. % of 35% aqueous hydrogen peroxide. The support substrate is immersed in the etching solution for about 3 minutes, whereupon the carbon black 201 is left out only on the end faces of the insulting film 61 as shown in FIG. 55. The carbon black 201 adsorbing on the respective surfaces of the copper foils 62, 62, is removed by etching the copper foils 62, 62 by a depth of about 1 μm from the respective surfaces.
(f) A rust preventive treatment is applied in a rust preventive liquid at 25° C. This step may be dispensed with.
(g) Copper electroplating is applied at room temperature in a copper sulfate solution at current density of, for example, 2 A/dm² for 30 minutes. By so doing, as shown in FIG. 56, a copper plating film 74a is formed on the respective surfaces of the copper foils 62, 62, and a through-hole copper plating film 74b is formed inside the respective through-holes as well, thereby rendering the copper foils 62, 62 to become electrically continuous with each other.

A thirteenth embodiment of a method of fabricating the semiconductor device shown in FIG. 41, according to the invention, is described hereinafter.

The method of fabricating the semiconductor device shown in FIG. 41 is the same as the method of fabricating the semiconductor device according to the twelfth embodiment of the invention except that the previously-described process step for forming the solder bumps (12) is dispensed with. With the present method, a high melting point solder 69 is caused to reach substantially the respective ends of the through-holes, on the exposure side of respective elements.

A fourteenth embodiment of a method of fabricating the semiconductor device, shown in FIGS. 42A, 42B, according to the invention is described hereinafter.

With the present embodiment, the heat radiation sheet is extended in order to enhance heat radiation property thereof.

That is, the method of fabricating the semiconductor device according to fourteenth embodiment is the same as that for the ninth embodiment except that the heat radiation sheet 66 is not only formed at a position directly under the binding electrode 64 of the semiconductor element 70 as in the case of the fabrication process according to the ninth embodiment, but also is extended toward the left-hand side in the figure as shown in, for example, FIG. 42A. With the configuration as described, the heat radiation sheet 66 has an area larger than that for the ninth embodiment, so that heat radiation property thereof is further enhanced.

With the embodiments of the invention, described hereinbefore, the nickel-gold film is shown to cover the entire surface of the heat radiation sheet 66, however, the nickel-gold film may be formed only in regions where the solder bump 102 are to be connected, and solder plating or tin plating may be applied to other regions.

Further, there has been described in detail a case where the insulting film is made out of the aramid non-woven fabric epoxy, but use may be made of polyimide, and so forth, for the insulting film.

Still further, with the embodiments of the invention, described hereinbefore, there has been described in detail a case where a pair of the binding electrode, and the heat radiation sheet as well as a pair of the respective draw-out electrodes and the respective connection electrodes has the through-hole, respectively, however, the invention can be applied to a case where any one of the pairs has the through-hole, respectively, while the other pairs have no through-hole, and holes are bored in the insulting film 61 by us of, for example, a laser and so forth, thereby connecting the binding electrode or the respective draw-out electrodes therewith through the intermediary of the respective bumps.

Yet further, with the embodiments of the invention, described hereinbefore, the bore of each of the through-holes 101 has been set to, for example, 0.3 mm, however, the bore may be of any suitable size as long as the bore is sufficient for implementing connection, and in particular, one located under the semiconductor element 70 may be larger than 0.3 mm, or may be square in cross section, slightly smaller in size than the semiconductor element 70.

1. A semiconductor device comprising elements including:
an insulting film;
a binding electrode, and draw-out electrodes, formed over the insulting film, on one side thereof;
a semiconductor element connected to the top of the binding electrode through the intermediary of an electrically conductive material;
wires interconnecting electrodes of the semiconductor element, and the draw-out electrodes, respectively; and
an insulating resin encapsulating the elements, wherein a heat radiation sheet for radiating heat of the binding electrode, and solder balls connected with the draw-out electrodes, respectively; are provided on the insulting film, on the other side thereof.

2. A semiconductor device according to claim 1, wherein the heat radiation sheet is connected with the binding electrode via an opening through the intermediary of an electrically conductive and thermally conductive substance.

3. A semiconductor device according to claims 1 or 2, wherein the insulting film is made out of an aramid non-woven fabric epoxy.

4. A semiconductor device comprising:
a heat resistant and deformable insulting film;
a binding electrode, and draw-out electrodes, formed over the top surface of the insulting film;
a semiconductor element connected to the top of the binding electrode through the intermediary of an electrically conductive substance;
wires interconnecting electrodes of the semiconductor element, and the draw-out electrodes, respectively;
an insulating resin encapsulating the entire top surface side of the insulting film;
openings formed in the insulting film, so as to correspond to the back surfaces of the binding electrode, and the draw-out electrodes, respectively; and
bumps connected with the draw-out electrodes, respectively, through the respective openings.

5. A semiconductor device according to claim 4, wherein the insulting film is made out of an aramid non-woven fabric epoxy film.

6. A semiconductor device comprising:
a semiconductor element;
a binding electrode connected to the semiconductor element through the intermediary of an electrically conductive substance, doubling as a heat radiation sheet, and draw-out electrodes; and
an insulating resin encapsulating the top surface side of the semiconductor element, the binding electrode doubling as the heat radiation sheet, and the draw-out electrodes, so as not to be exposed to the atmosphere, while exposing the back surface side of the binding electrode doubling as the heat radiation sheet, and the draw-out electrodes, to the atmosphere;
wherein the binding electrode, doubling as the heat radiation sheet, has a heat radiation region located outside of a region of the semiconductor element in a plan view when the semiconductor element is disposed over the binding electrode.

7. A semiconductor device comprising elements including:
an insulting film;
a binding electrode, and draw-out electrodes, provided, on one face side of the insulting film;
a semiconductor element disposed over the binding electrode through the intermediary of an electrically conductive layer formed on the binding electrode;
wires interconnecting electrodes of the semiconductor element, and the draw-out electrodes, respectively;
an insulating resin encapsulating the elements; and
connection electrodes and a heat radiation sheet, provided on the other face side of the insulting film, so as to correspond to the draw-out electrodes and the binding electrode, respectively;
wherein at least one pair comprised of the binding electrode, and the heat radiation sheet or one of the draw-out electrodes and one of the connection electrodes has a through-hole penetrating through the insulting film, thereby being connected with each other through the intermediary of an electrically conductive material filled in the through-hole.

8. A semiconductor device according to claim 7, wherein the electrically conductive material filled in the through-hole is composed mainly of substance of the electrically conductive layer for securely holding the binding electrode, and the semiconductor element together, and/or substance for forming solder bumps.

9. A method of fabricating a semiconductor device comprising the steps of:
forming a binding electrode, and draw-out electrodes, by etching an electrode material provided over a heat resistant and deformable insulting film;
providing openings in the insulting film, so as to correspond to the back surface side of the binding electrode, and the draw-out electrodes, respectively;
connecting a semiconductor element onto the binding electrode through the intermediary of an electrically conductive substance;
bonding electrodes of the semiconductor element, to the draw-out electrodes, respectively;
encapsulating the entire surface of the insulting film, on the side of the semiconductor element, with an insulating resin; and
connecting the draw-out electrodes with bumps, via the openings, respectively.

10. A method of fabricating a semiconductor device according to claim 9, wherein the insulting film is made out of an aramid non-woven fabric epoxy film.

11. A method of fabricating a semiconductor device comprising the steps of:
forming a binding electrode doubling as a heat radiation sheet, and draw-out electrodes over a support substrate;
connecting a semiconductor element onto the binding electrode over the support substrate, doubling as the heat radiation sheet, through the intermediary of an electrically conductive substance;
bonding electrodes of the semiconductor element, to the draw-out electrodes, respectively;
encapsulating the semiconductor element, the binding electrode doubling as the heat radiation sheet, the draw-out electrodes, provided over the support substrate, with an insulating resin; and
stripping the support substrate from the interfaces thereof, with the back surface of the binding electrode doubling as the heat radiation sheet, the respective back surfaces of the draw-out electrodes and the insulating resin, thereby exposing the respective back surface sides of the binding electrode doubling as the heat radiation sheet and the draw-out electrodes;
wherein the step of forming the binding electrode doubling as the heat radiation sheet is the step of forming the binding electrode such that the binding electrode, has a heat radiation region located outside of a region of the semiconductor element in a plan view when the semiconductor element is disposed over the binding electrode.

12. A method of fabricating a semiconductor device according to claim 11, wherein the support substrate is made out of stainless steel, and the binding electrode doubling as the heat radiation sheet, and the draw-out electrodes are formed by a plating method.

13. A method of fabricating a semiconductor device according to claim 11, wherein the step of stripping the support substrate from the interfaces thereof, with the back surface of the binding electrode doubling as the heat radiation sheet, the respective back surfaces of the draw-out electrodes and the insulating resin, thereby exposing the respective back surface sides of the binding electrode doubling as the heat radiation sheet and the draw-out electrodes is the step of stripping an adhesive film formed on the support substrate, and the support substrate from, the interfaces thereof, with the back surface of the binding electrode doubling as the heat radiation sheet, the respective back surfaces of the draw-out electrodes, and the insulating resin, thereby exposing the respective back surface sides of the binding electrode doubling as the heat radiation sheet and the draw-out electrodes.

14. A method of fabricating a semiconductor device according to claims 11 or 13, wherein the support substrate is formed of glass epoxy resin and the adhesive film is formed of a silicon resin.
